(19) United States
(12) Patent Application Publication
(10) Pub. No.: US 2026/0204811 A1
(43) Pub. Date: Jul. 16, 2026

(54) ELECTRICAL CONNECTION UNIT

(71) Applicant: YAZAKI CORPORATION, Tokyo (JP)

(72) Inventors: Kazutaka Uki, Kakegawa-shi (JP); Yuuki Miyazawa, Kakegawa-shi (JP); Mitsuru Saito, Kakegawa-shi (JP); Tatsuya Shiraishi, Kakegawa-shi (JP)

(21) Appl. No.: 19/442,949

(22) Filed: Jan. 7, 2026

(30) Foreign Application Priority Data
Jan. 15, 2025 (JP) 2025-005459

(51) Int. Cl. H01R 4/62; H01R 4/34

(52) U.S. Cl. CPC H01R 4/62; H01R 4/34

(57) ABSTRACT

An electrical connection unit includes a first electronic component, a second electronic component, a first routing portion, and a second routing portion. The second electronic component has a smaller amount of heat generation than the first electronic component during energization. The first routing portion is connected to a first terminal of the second electronic component, and electrically connects the first electronic component to the second electronic component. The second routing portion is connected to a second terminal of the second electronic component. The first routing portion is formed of at least one first metal plate portion. The second routing portion is formed of a plurality of second metal plate portions that are disposed to overlap. The first metal plate portion contains a first material. The second metal plate portion contains a second material. A thermal conductivity of the first material is higher than a thermal conductivity of the second material.

### BACKGROUND OF THE INVENTION

### Field of the Invention

Embodiments of the present invention relate to an electrical connection unit.

Priority is claimed on Japanese Patent Application No. 2025-005459 filed in Japan on January 15, 2025, the content of which is incorporated herein by reference.

### Description of the Related Art

There is an electrical connection unit including an electronic component and a routing member electrically connected to the electronic component.

### Prior Art Document

### Patent Document

Japanese Unexamined Patent Application, First Publication No. 2024-037492

### SUMMARY OF THE INVENTION

It is expected to improve a heat dissipation property of an electrical connection unit and reduce cost thereof.

An embodiment provides an electrical connection unit capable of improving a heat dissipation property and reducing cost.

An electrical connection unit according to an embodiment includes a first electronic component, a second electronic component, a first routing portion, and a second routing portion. The second electronic component includes a first terminal and a second terminal, and has a smaller amount of heat generation than the first electronic component during energization. The first routing portion is connected to the first terminal of the second electronic component directly or via a routing member, and electrically connects the first electronic component to the second electronic component. The second routing portion is connected to the second terminal of the second electronic component directly or via a routing member. The first routing portion is formed of at least one first metal plate portion. The second routing portion is formed of a plurality of second metal plate portions that are disposed to overlap. The first metal plate portion contains a first material. The second metal plate portion contains a second material. A thermal conductivity of the first material is higher than a thermal conductivity of the second material.

An electrical connection unit according to an embodiment includes a first electronic component, a second electronic component, a first component, a first routing portion, and a second routing portion. The second electronic component includes a first terminal and a second terminal. The first component has a smaller amount of heat generation than the first electronic component during energization. The first routing portion is connected to the first terminal of the second electronic component directly or via a routing member, and electrically connects the first electronic component to the second electronic component. The second routing portion is connected to the second terminal of the second electronic component directly or via a routing member, and electrically connects the second electronic component to the first component. The first routing portion is formed of at least one first metal plate portion. The second routing portion is formed of a plurality of second metal plate portions that are disposed to overlap. The first metal plate portion contains a first material. The second metal plate portion contains a second material. A thermal conductivity of the first material is higher than a thermal conductivity of the second material.

An electrical connection unit according to an embodiment includes a first electronic component, a second electronic component, a third electronic component, a fourth electronic component, a first routing portion, and a second routing portion. The third electronic component has a smaller amount of heat generation than the first electronic component during energization. The first routing portion electrically connects the first electronic component to the second electronic component. The second routing portion electrically connects the third electronic component to the fourth electronic component. The first routing portion is formed of at least one first metal plate portion. The second routing portion is formed of a plurality of second metal plate portions that are disposed to overlap. The first metal plate portion contains a first material. The second metal plate portion contains a second material. A thermal conductivity of the first material is higher than a thermal conductivity of the second material.

According to one embodiment, it is possible to improve the heat dissipation property and reduce the cost.

### BRIEF DESCRIPTION OF THE DRAWINGS

FIG. 1 is a partially exploded perspective view of an electrical connection unit according to an embodiment.

FIG. 2 is a perspective view illustrating a first structure according to the embodiment.

FIG. 3 is a perspective view for describing an electronic component and a connection component according to the embodiment.

FIG. 4 is a plan view illustrating the first structure of the embodiment.

FIG. 5 is a perspective view illustrating a routing structure of the first structure according to the embodiment.

FIG. 6 is a partially exploded view of the routing structure of the first structure according to the embodiment.

FIG. 7 is a cross-sectional view taken along line F7-F7 illustrated in FIG. 4.

FIG. 8 is a perspective view illustrating a modification example of the first structure according to the embodiment.

FIG. 9 is a perspective view illustrating a second structure according to the embodiment.

FIG. 10 is a perspective view illustrating a routing structure of the second structure according to the embodiment.

FIG. 11 is a plan view illustrating the second structure according to the embodiment.

FIG. 12 is a cross-sectional view taken along line F12-F12 of the structure illustrated in FIG. 11.

FIG. 13 is a perspective view illustrating a first modification example of the second structure according to the embodiment.

FIG. 14 is a perspective view illustrating a second modification example of the second structure according to the embodiment.

FIG. 15 is a perspective view illustrating a third modification example of the second structure according to the embodiment.

FIG. 16 is a perspective view illustrating a third structure according to the embodiment.

FIG. 17 is a cross-sectional view illustrating a third structure according to the embodiment.

FIG. 18 is a perspective view illustrating a modification example of the third structure according to the embodiment.

FIG. 19 is a perspective view illustrating a fourth structure according to the embodiment.

FIG. 20 is a perspective view illustrating a routing structure of the fourth structure according to an embodiment.

FIG. 21 is a plan view illustrating the fourth structure according to the embodiment.

FIG. 22 is a cross-sectional view taken along line F22-F22 of the structure illustrated in FIG. 21.

FIG. 23 is a perspective view illustrating a fifth structure according to the embodiment.

FIG. 24 is a plan view illustrating the fifth structure according to the embodiment.

FIG. 25 is a cross-sectional view taken along line F25-F25 of the structure illustrated in FIG. 24.

### DETAILED DESCRIPTION OF THE INVENTION

Hereinafter, embodiments will be described with reference to the drawings. In the following description, constitutions having the same or similar functions are denoted by the same reference numbers. Redundant descriptions of these constitutions may be omitted. The constitution to be described below does not limit the scope of the embodiment.

In the present disclosure, the terms are defined as follows. The term “connection” is not limited to a mechanical connection, and may include an electrical connection. That is, the term “connection” is not limited to a case where two elements that are connection targets are directly connected, and may include a case where two elements that are connection targets are connected with another element interposed therebetween. The term “facing” or “overlapping” indicates that virtual projection images of two target objects overlap each other when viewed from a specific direction. That is, “facing” or “overlapping” is not limited to a case where two target objects directly face each other, and may include a case where two target objects face each other in a state in which another member or a gap exists between the two target objects. “Parallel”, “orthogonal”, or “the same” may include “substantially parallel”, “substantially orthogonal”, or “substantially the same”, respectively.

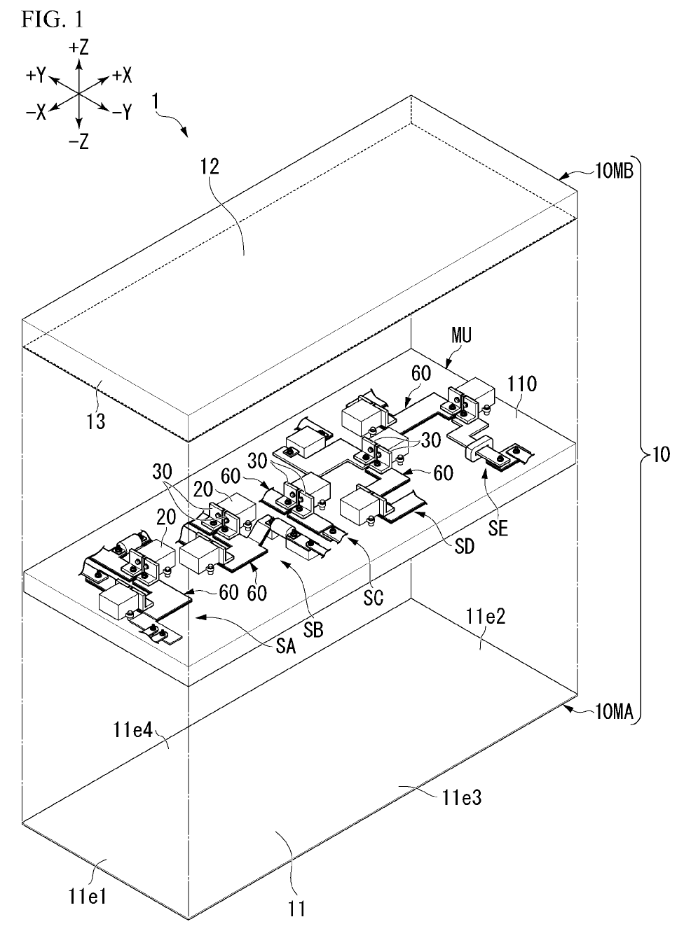

In the present disclosure, a +X direction, a -X direction, a +Y direction, a -Y direction, a +Z direction, and a -Z direction are defined as follows. The +X direction is, for example, a direction from a first end portion 11e1 to a second end portion 11e2 of a lower wall 11 of an enclosure 10 that will be described later (see FIG. 1). The -X direction is a direction opposite to the +X direction. Hereinafter, in a case where the +X direction and the -X direction are not distinguished, the directions will be simply referred to as “X direction”. The +Y direction and the -Y direction are directions intersecting (for example, orthogonal to) the X direction. The +Y direction is, for example, a direction from a third end portion 11e3 to a fourth end portion 11e4 of the lower wall 11 of the enclosure 10 that will be described later (see FIG. 1). The -Y direction is a direction opposite to the +Y direction. Hereinafter, in a case where the +Y direction and the -Y direction are not distinguished, the directions will be simply referred to as “Y direction”. The +Z direction and the -Z direction are directions intersecting (for example, orthogonal to) the X direction and the Y direction. The +Z direction is a direction from a lower wall 11 of the enclosure 10 that will be described later toward a main body MU (see FIG. 1). The -Z direction is a direction opposite to the +Z direction. Hereinafter, in a case where the +Z direction and the -Z direction are not distinguished, the directions will be simply referred to as “Z direction”.

Hereinafter, in a case where the X direction and the Y direction are not distinguished, the directions may be referred to as “horizontal direction”. Hereinafter, the Z direction may be referred to as “vertical direction”. Hereinafter, the +Z direction side may be referred to as “upper”, and the -Z direction side may be referred to as “lower”. However, these expressions are expressions for convenience of description, and do not limit a gravity direction of an electrical connection unit 1 (an installation posture of the electrical connection unit 1).

### Embodiment

### 1. Constitution of Electrical Connection Unit

FIG. 1 is a partially exploded perspective view of an electrical connection unit 1 according to an embodiment. The electrical connection unit 1 is, for example, an in-vehicle device mounted on a vehicle such as an electric vehicle (EV), a hybrid electric vehicle (HEV), or a plug-in hybrid electric vehicle (PHEV). The electrical connection unit 1 may be referred to as an “electrical connection box” or a “junction box”, for example. However, the electrical connection unit 1 is not limited to a box-shaped device. The electrical connection unit 1 includes, for example, an enclosure 10 and a main body MU.

### Enclosure

The enclosure 10 is a member forming the exterior of the electrical connection unit 1. The enclosure 10 has, for example, a flat box shape. The enclosure 10 is made of, for example, a synthetic resin and has an insulating property. The enclosure 10 accommodates the main body MU. The enclosure 10 has, for example, a lower wall 11 (first wall portion), an upper wall 12 (second wall portion), and a peripheral wall 13 (third wall portion). The lower wall 11 covers at least a part of the main body MU from below (-Z direction side). The upper wall 12 covers at least a part of the main body MU from above (+Z direction side). The peripheral wall 13 surrounds the periphery of the main body MU.

The enclosure 10 includes, for example, a first member 10MA including the lower wall 11 and a second member 10MB including the upper wall 12 and the peripheral wall 13. In the present embodiment, the enclosure 10 is formed by combining the first member 10MA and the second member 10MB. The lower wall 11 may be formed of an insulating sheet or the like instead of the wall having rigidity. A part or the whole of the enclosure 10 may be omitted.

### Main Body

The main body MU is a portion that performs a main function (for example, switching of electrical connection states or overcurrent protection) of the electrical connection unit 1. The main body MU may be referred to as a “circuit constitution body”. The main body MU includes, for example, a plurality of electronic components 20, a plurality of connection components 30, a plurality of routing structures 60, and a base member 110. Here, the base member 110 will be described first.

The base member 110 is a member that supports one or more electronic components 20 and/or one or more routing structures 60 inside the enclosure 10. The base member 110 is made of, for example, a synthetic resin and has an insulating property. The base member 110 is disposed between the electronic component 20 and the routing structure 60 and the lower wall 11 of the enclosure 10 in the Z direction. The base member 110 is fixed to the lower wall 11 of the enclosure 10, for example. The base member 110 supports the one or more electronic components 20 and/or the one or more routing structures 60 from below. The base member 110 may be a wall portion provided in the horizontal direction, a structure in which a plurality of ribs standing in the vertical direction are combined, or the like. The base member 110 may be formed of a part of the enclosure 10.

Next, a structure of each portion of the main body MU will be described. The main body MU includes, for example, a first structure SA, a second structure SB, a third structure SC, a fourth structure SD, and a fifth structure SE. For example, the routing structures 60 included in each of the first structure SA, the second structure SB, the third structure SC, the fourth structure SD, and the fifth structure SE are electrically connected to each other, for example, to form one circuit. One or more of the first structure SA, the second structure SB, the third structure SC, the fourth structure SD, and the fifth structure SE may be electrically separated from other structures. Further, the main body MU does not need to have all these structures. The main body MU may have one or more of the first to fifth structures SA, SB, SC, SD, and SE. Hereinafter, each of the first to fifth structures SA, SB, SC, SD, and SE will be described.

### 2. First Structure

First, the first structure SA will be described.

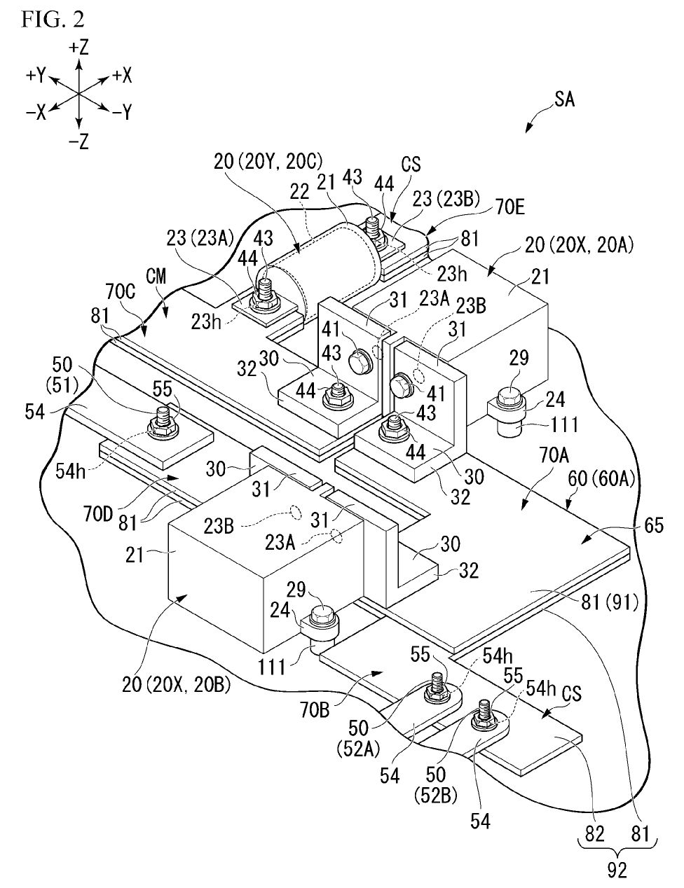

FIG. 2 is a perspective view illustrating the first structure SA. The first structure SA includes, for example, a plurality of electronic components 20, a plurality of connection components 30, a plurality of external connection terminals 50, and a routing structure 60.

### 2.1 Electronic Component

The electronic component 20 is an electronic component mounted in accordance with a function required for the main body MU. The electronic component 20 is, for example, a connector, a fuse, a relay (for example, a mechanical relay or a semiconductor relay), a capacitor, a branch component, any of various sensors (for example, a current sensor or a voltage sensor), an electronic control unit, or an electronic component unit in which two or more of these are unitized. The type of the electronic component 20 is not limited to the above example. The electronic component 20 is, for example, a heat generating component that generates heat at the time of energization.

In the present embodiment, the main body MU includes, as the electronic component 20, the electronic component 20X of the first aspect and the electronic component 20Y of the second aspect. Hereinafter, in a case where the electronic component 20X of the first aspect and the electronic component 20Y of the second aspect are not distinguished, the electronic components will be simply referred to as “electronic component 20”.

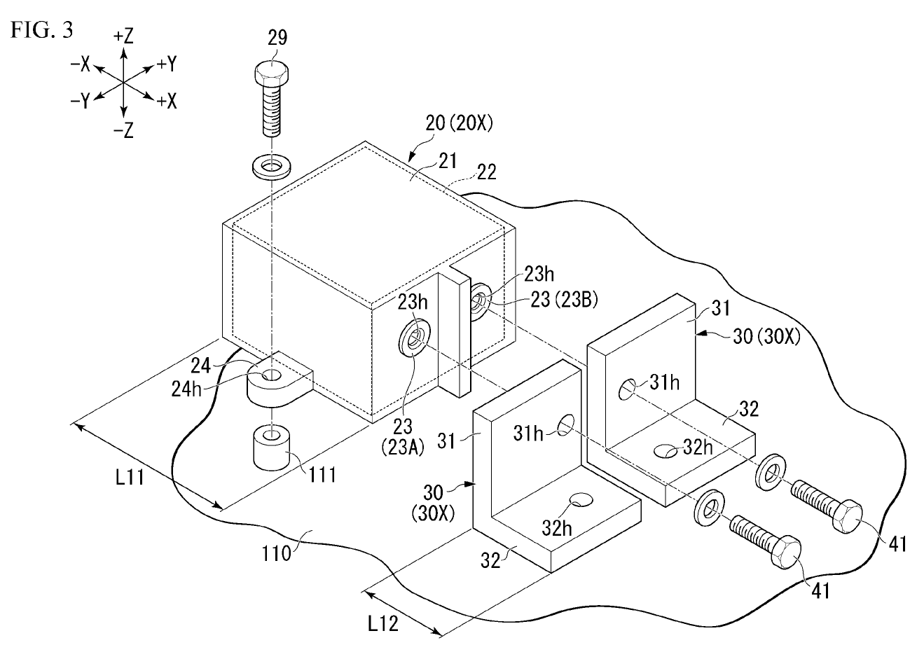

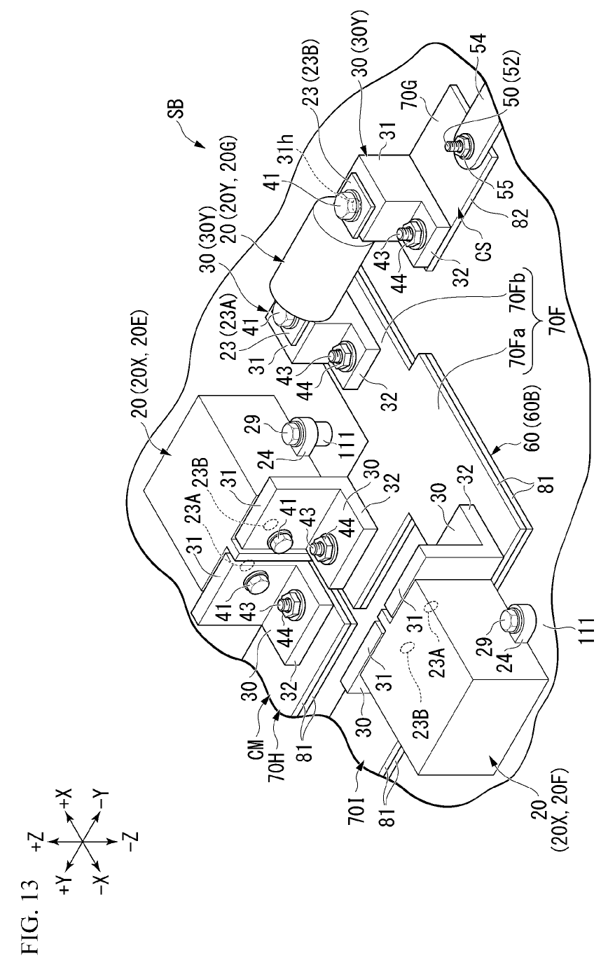

In the present embodiment, the main body MU includes, as the connection component 30, a connection component 30X (see FIG. 3) of the first aspect corresponding to the electronic component 20X and a connection component 30Y (see FIG. 13) of the second aspect corresponding to the electronic component 20Y. Hereinafter, in a case where the connection component 30X of the first aspect and the connection component 30Y of the second aspect are not distinguished, the connection components will be simply referred to as “connection component 30”. The connection component 30 is an example of a “routing member”.

### 2.2 Electronic Component of First Aspect

FIG. 3 is a perspective view for describing the electronic component 20X and the connection component 30X of the first aspect. The electronic component 20X includes, for example, a case 21, a component body 22, a plurality of terminals 23, and a plurality of attachment portions 24 (only one is illustrated in FIG. 3).

### Case

The case 21 is an outer frame member that forms most of the outer frame of the electronic component 20. The case 21 is made of, for example, a synthetic resin and has an insulating property. The case 21 accommodates the component body 22. The case 21 and the component body 22 may be integrally formed.

### Component Body

The component body 22 is a portion that performs a main function of the electronic component 20. For example, in a case where the electronic component 20 is a relay, the component body 22 includes a switch (for example, a contact) that switches between a conductive state and a non-conductive state. For example, in a case where the electronic component 20 is a fuse, the component body 22 includes a fusible portion that melts when an overcurrent flows. For example, in a case where the electronic component 20 is a capacitor, the component body 22 includes a portion that accumulates electric charge.

### Terminal

Each of the terminals 23 is an electrical connection portion exposed to the outside of the case 21. The terminal 23 is electrically connected to the component body 22 inside the case 21. In the present embodiment, the electronic component 20 includes a terminal 23A and a terminal 23B as the plurality of terminals 23. One of the terminal 23A and the terminal 23B is a terminal on the positive electrode side. The other of the terminal 23A and the terminal 23B is a terminal on the negative electrode side. One of the terminal 23A and the terminal 23B is an example of a “first terminal”. The other of the terminal 23A and the terminal 23B is an example of a “second terminal”.

In the electronic component 20X of the first aspect, the terminal 23A and the terminal 23B are provided at one end portion of the electronic component 20X in the horizontal direction (for example, the X direction). The terminal 23A and the terminal 23B are disposed to be arranged in the horizontal direction (for example, the Y direction). Each of the terminal 23A and the terminal 23B is directed in the horizontal direction (for example, the X direction).

Each terminal 23 has an attachment hole 23h into which a fastening member 41 (for example, a screw or a bolt) that will be described later is inserted. The attachment hole 23h is open in the horizontal direction (for example, the +X direction). In the present embodiment, the fastening member 41 is inserted into the attachment hole 23h from the X direction (for example, from the +X direction side). An inner circumferential surface of the attachment hole 23h of the electronic component 20X has a screw groove. The attachment hole 23h is a bottomed hole provided in the electronic component 20X. In the present disclosure, the “attachment hole” is not limited to a hole having a screw groove, and may be a hole having no screw groove.

### Attachment Portion

The attachment portion 24 is a portion for fixing the electronic component 20X. For example, the attachment portion 24 overlaps a fixing portion 111 (for example, a boss) provided on the base member 110 from the Z direction. The attachment portion 24 has an attachment hole 24h into which the fastening member 29 (for example, a screw or a bolt) is inserted. The attachment hole 24h is open in the Z direction. The fastening member 29 that has passed through the attachment hole 24h is fixed to the fixing portion 111 of the base member 110, and thus the attachment portion 24 is attached to the base member 110. The electronic component 20X is fixed to the base member 110 by the attachment portion 24 being attached to the base member 110.

### 2.3 Connection Component of First Aspect

In the present embodiment, the connection component 30 is a member that electrically connects the electronic component 20 to the routing structure 60. For example, in a case where the terminal 23 of the electronic component 20 and the routing structure 60 are located at different heights in the Z direction, the connection component 30 is disposed between the terminal 23 of the electronic component 20 and the routing structure 60 to electrically connect the electronic component 20 to the routing structure 60. The connection component 30 may be referred to as a “vertical routing member”. For example, a length L12 of the connection component 30 in the longitudinal direction of the electronic component 20 is shorter than a length L11 of the electronic component 20 in the longitudinal direction of the electronic component 20.

FIG. 3 illustrates the connection component 30X of the first aspect corresponding to the electronic component 20X. The connection component 30X includes, for example, a first portion 31 and a second portion 32. In the present embodiment, the first portion 31 and the second portion 32 form one L-shaped connection component 30X.

### First Portion

The first portion 31 of the connection component 30X is a portion connected to the terminal 23 of the electronic component 20X. The first portion 31 is a plate-shaped or rectangular parallelepiped portion extending in the Z direction. The first portion 31 extends in the Z direction along one end portion (for example, an end portion in the X direction) of the electronic component 20X. The first portion 31 is a standing portion that stands in the Z direction with respect to the routing structure 60. The first portion 31 is adjacent to the terminal 23 of the electronic component 20X in the horizontal direction (for example, the X direction), and is connected to the terminal 23 of the electronic component 20X from the horizontal direction (for example, the X direction).

The first portion 31 of the connection component 30X has a first attachment hole 31h into which the fastening member 41 (for example, a screw or a bolt) is inserted. The first attachment hole 31h is open in the horizontal direction (for example, the X direction). The fastening member 41 that has passed through the first attachment hole 31h is engaged with the attachment hole 23h of the terminal 23 of the electronic component 20X, and thus the first portion 31 is physically and electrically connected to the terminal 23 of the electronic component 20X.

### Second Portion

The second portion 32 of the connection component 30X is a portion connected to the routing structure 60. The second portion 32 extends in the horizontal direction (for example, the X direction) from the end portion of the first portion 31 on the -Z direction side. The second portion 32 is a plate portion provided in the horizontal direction. The second portion 32 overlaps the routing structure 60 from the Z direction and is connected to the routing structure 60 from the Z direction.

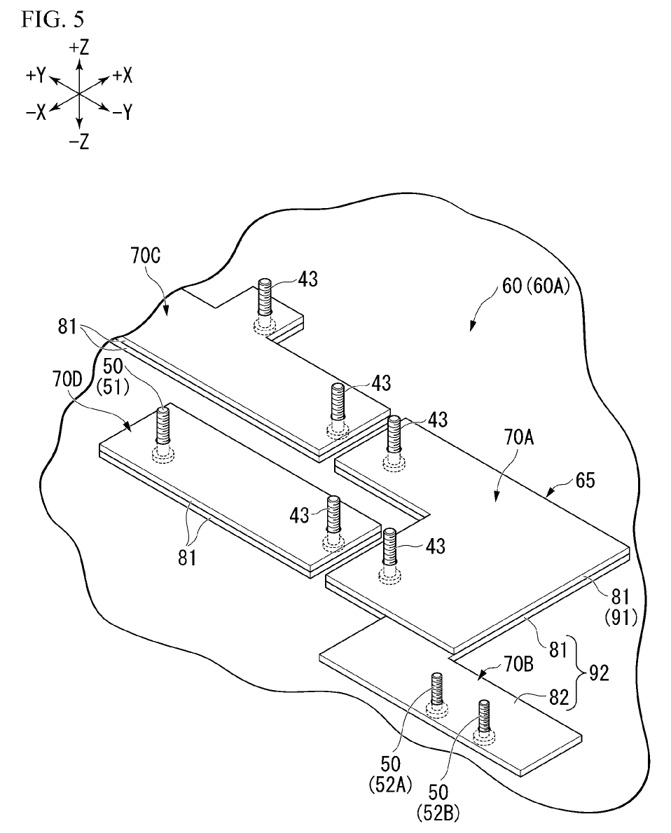

The second portion 32 of the connection component 30X has a second attachment hole 32h into which the fastening member 43 (for example, a screw or a bolt; and see FIG. 5) is inserted. The fastening member 43 protrudes from the routing structure 60 in the +Z direction. The fastening member 43 is, for example, a rivet bolt attached to the routing structure 60. The second attachment hole 32h is open in the Z direction. An engagement member 44 (for example, a nut; and see FIG. 2) is engaged with the tip of the fastening member 43 that has passed through the second attachment hole 32h, and thus the second portion 32 is physically and electrically connected to the routing structure 60. As a result, the connection component 30X electrically connects the electronic component 20X to the routing structure 60.

### 2.4 Electronic Component of Second Aspect

Next, referring to FIG. 2 again, the electronic component 20Y of the second aspect will be described. The electronic component 20Y of the second aspect is an electronic component in which two terminals 23 are separately disposed at both end portions of the electronic component 20Y in the horizontal direction. The electronic component 20Y includes, for example, a case 21, a component body 22, and a plurality of terminals 23. Note that, in the electronic component 20Y, constitutions having functions similar to those of the electronic component 20X are denoted by the same reference numerals. In the description regarding the electronic component 20Y, it can be read the “electronic component 20X” as the “electronic component 20Y” in the description regarding the electronic component 20X described above.

As described above, the terminal 23A and the terminal 23B of the electronic component 20Y are disposed separately at both end portions of the electronic component 20Y in the horizontal direction (for example, the X direction). Each terminal 23 has the attachment hole 23h into which the fastening member 43 (for example, a screw or a bolt) is inserted. The attachment hole 23h is open in the Z direction. The attachment hole 23h does not have, for example, a screw groove. The engagement member 44 (for example, a nut) is engaged with the tip of the fastening member 43 that has passed through the attachment hole 23h, and thus the terminal 23 of the electronic component 20Y is physically and electrically connected to the routing structure 60.

### 2.5 Connection Component of Second Aspect

As described above, the electronic component 20Y may be connected to the routing structure 60 via the connection component 30Y (see FIG. 13) of the second aspect instead of being directly connected to the routing structure 60. The connection component 30Y includes, for example, a first portion 31 and a second portion 32.

### First Portion

The first portion 31 of the connection component 30Y is a portion connected to the terminal 23 of the electronic component 20Y. The first portion 31 is a rectangular parallelepiped portion extending in the Z direction. The first portion 31 is adjacent to the terminal 23 of the electronic component 20Y in the Z direction, and is connected to the terminal 23 of the electronic component 20Y from the Z direction.

The first portion 31 of the connection component 30Y has a first attachment hole 31h into which the fastening member 41 (for example, a screw or a bolt) is inserted. The first attachment hole 31h is open in the Z direction. The first attachment hole 31h of the connection component 30Y has a screw groove. The fastening member 41 that has passed through the attachment hole 23h of the terminal 23 of the electronic component 20Y is engaged with the first attachment hole 31h, and thus the first portion 31 is physically and electrically connected to the terminal 23 of the electronic component 20Y.

### Second Portion

The second portion 32 of the connection component 30Y is a portion connected to the routing structure 60. The second portion 32 extends in the horizontal direction (for example, the X direction) from the end portion of the first portion 31 on the -Z direction side. Details of the second portion 32 of the connection component 30Y are similar to the details of the second portion 32 of the connection component 30X described above.

### 2.6 Electronic Component of First Structure

Next, the electronic component 20 of the first structure SA will be described. The first structure SA includes three electronic components 20A, 20B, and 20C as the plurality of electronic components 20.

Each of the electronic components 20A and 20B is, for example, a component included in a main circuit CM of the electrical connection unit 1. In the present disclosure, a “component included in a main circuit” is, for example, a component through which a current (main current) having a first current value as an average current value flows. In the present disclosure, the “main current” is, for example, a current that is output to or input from an external device as a current used for driving a device (such as a vehicle). The external device is a power conversion device such as an inverter, a battery, or the like.

The electronic components 20A and 20B are electrically connected in series to each other, for example. Each of the electronic components 20A and 20B is, for example, a relay. However, the types of the electronic components 20A and 20B are not limited to the above examples. Each of the electronic components 20A and 20B has a greater amount of heat generation than an electronic component 20C that will be described later during energization. The electronic component 20A is an example of a “first electronic component”. The electronic component 20B is an example of a “second electronic component”.

On the other hand, the electronic component 20C is, for example, a component included in a sub-circuit CS of the electrical connection unit 1. In the present disclosure, a “component included in a sub-circuit” is, for example, a component through which a current having a second current value smaller than the first current value flows as an average current value. In the present disclosure, a “sub-circuit” is a circuit through which the main current described above does not flow but a current having a smaller current value than that of the main current flows.

The electronic component 20C is, for example, a fuse. However, the type of the electronic component 20C is not limited to the above example. The electronic component 20 included in the sub-circuit CS may be a relay or any of various sensors smaller than the electronic component 20 included in the main circuit CM.

### 2.7 External Connection Terminal of First Structure

Next, the external connection terminal 50 of the first structure SA will be described. The external connection terminal 50 is a terminal to which a bus bar 54 for external connection can be attached. The bus bar Bfor external connection is a routing member that connects the electrical connection unit 1 to an external device. In the present disclosure, the “external device” is a device (for example, a power conversion device such as an inverter, a battery, any of various sensors, or a control device) or the like located outside the electrical connection unit 1.

For example, the external connection terminal 50 is a component protruding in the +Z direction from the routing structure 60. In the present embodiment, the external connection terminal 50 is formed of a shaft of the fastening member 43 attached to the routing structure 60. The bus bar 54 for external connection has an attachment hole 54h into which the external connection terminal 50 is inserted. In the present embodiment, an engagement member 55 (for example, a nut) is engaged with the tip of the external connection terminal 50 inserted into the attachment hole 54h, and thus the bus bar 54 for external connection is physically and electrically connected to the external connection terminal 50. The external connection terminal 50 has a smaller amount of heat generation than the electronic component 20A during energization. The external connection terminal 50 has a smaller amount of heat generation than the electronic component 20B during energization. The external connection terminal 50 has a smaller amount of heat generation than the electronic component 20C during energization.

The first structure SA includes three external connection terminals 51A, 52A, and 52B as the plurality of external connection terminals 50. The external connection terminal 51 is, for example, a component included in the main circuit CM of the electrical connection unit 1. The external connection terminal 51 is electrically connected in series to the two electronic components 20A and 20B. A current (main current) having the first current value as an average current value flows through the external connection terminal 51.

External connection terminals 52A and 52B are, for example, components included in the sub-circuit CS of the electrical connection unit 1. For example, the external connection terminals 52A and 52B are electrically connected in parallel to the electronic component 20B when viewed from the electronic component 20A. The external connection terminals 52A and 52B are electrically connected in parallel to each other. The external connection terminals 52A and 52B are disposed to be arranged in the Y direction, for example. A current having a second current value smaller than the first current value as an average current value flows through the external connection terminals 52A and 52B. For example, currents output to various sensors or control devices flow through the external connection terminals 52A and 52B. The external connection terminal 52A is an example of a “first component”. The external connection terminal 52B is an example of a “second component”. Each of the external connection terminals 52A and 52B has a smaller amount of heat generation than the external connection terminal 51 during energization.

### 2.8 Routing Structure

Next, the routing structure 60 of the first structure SA will be described.

The first structure SA has a routing structure 60A as an example of the routing structure 60. The routing structure 60A includes, for example, a routing structure 65, a routing portion 70C, a routing portion 70D, and a routing portion 70E.

The routing structure 65 is provided over, for example, the electronic component 20A, the electronic component 20B, and the external connection terminals 52A and 52B. The routing structure 65 electrically connects the electronic component 20A, the electronic component 20B, and the external connection terminals 52A and 52B to each other. The routing structure 65 includes, for example, a routing portion 70A and a routing portion 70B.

### Routing Portion 70A

The routing portion 70A is provided over the electronic component 20A and the electronic component 20B, and electrically connects the electronic component 20A to the electronic component 20B. The routing portion 70A is a routing portion included in the main circuit CM of the electrical connection unit 1. The routing portion 70A is an example of a “first routing portion”.

The routing portion 70A is formed of a first number (for example, two) of metal plate portions 81. The metal plate portion 81 is a plate portion provided in the horizontal direction. The metal plate portion 81 is made of, for example, aluminum or an aluminum alloy. The plate thickness (the thickness in the Z direction) of the metal plate portion 81 is, for example, 3 mm. The routing portion 70A is formed of a first number (for example, two) of metal plate portions 81 that are disposed to overlap in the Z direction. The plurality of metal plate portions 81 may be integrated through welding, machining, or the like, or may be separable from each other.

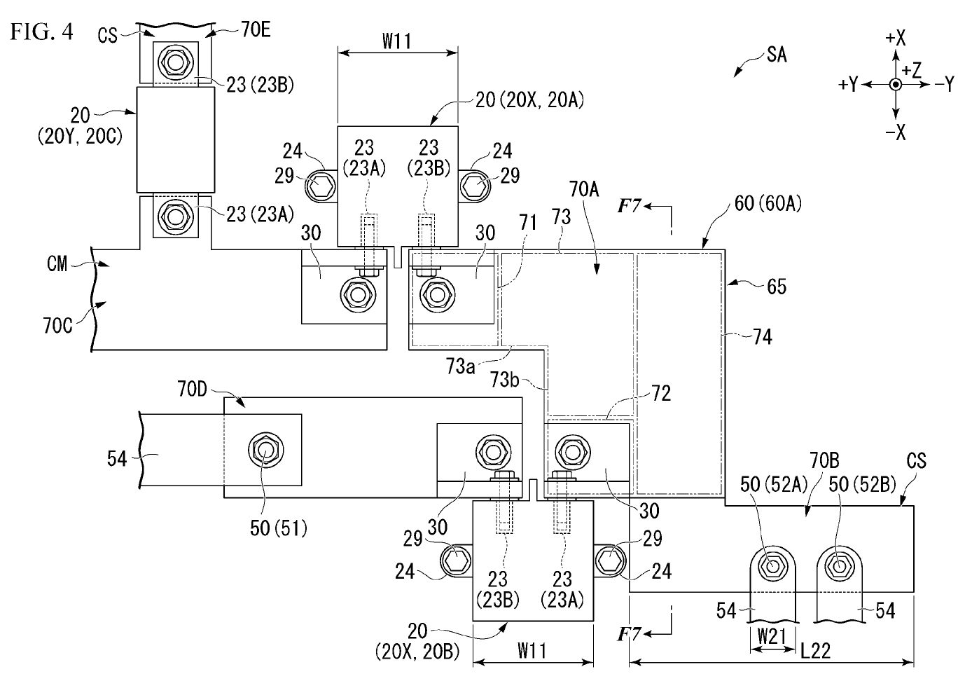

FIG. 4 is a plan view illustrating the first structure SA. The routing portion 70A includes, for example, a first connection portion 71, a second connection portion 72, an extending portion 73, and an expansion portion 74.

The first connection portion 71 is located at one end portion of the routing portion 70A. The first connection portion 71 overlaps the connection component 30 corresponding to the terminal 23B of the electronic component 20A when viewed from the Z direction. The first connection portion 71 is connected to the connection component 30 and is electrically connected to the terminal 23B of the electronic component 20A via the connection component 30. Note that the first connection portion 71 may be directly connected to the terminal 23B of the electronic component 20A without the connection component 30 interposed therebetween.

The second connection portion 72 is located at another end portion of the routing portion 70A. The second connection portion 72 overlaps the connection component 30 corresponding to the terminal 23A of the electronic component 20B when viewed from the Z direction. The second connection portion 72 is connected to the connection component 30 and is electrically connected to the terminal 23A of the electronic component 20B via the connection component 30. The second connection portion 72 may be directly connected to the terminal 23A of the electronic component 20B without the connection component 30 interposed therebetween.

The extending portion 73 extends between the first connection portion 71 and the second connection portion 72. The extending portion 73 includes a portion extending in the X direction or the Y direction. In the present embodiment, the extending portion 73 includes a first portion 73a extending from the first connection portion 71 in the -Y direction and a second portion 73b extending from the first portion 73a in the -X direction and connected to the second connection portion 72.

The expansion portion 74 is a portion where the routing portion 70A is expanded to an electrically unnecessary region, for example, in order to increase the heat capacity. Here, a direction (for example, the Y direction) in which the terminal 23A and the terminal 23B of the electronic component 20B are arranged will be referred to as a “first direction”. With the electronic component 20B as a reference, a side (+Y direction side) close to the electronic component 20A in the first direction will be referred to as a “first side”, and a side (-Y direction side) opposite to the first side will be referred to as a “second side”. In this case, the expansion portion 74 is expanded from the second connection portion 72 or the extending portion 73 to the second side (-Y direction side) and projects.

In the present embodiment, the expansion portion 74 is provided on the second side (-Y direction side) with respect to both the second connection portion 72 and the extending portion 73. That is, the expansion portion 74 extends in the X direction between a position adjacent to the second connection portion 72 in the Y direction and a position adjacent to the extending portion 73 in the Y direction. The expansion portion 74 extends in the X direction over the entire length of the extending portion 73 in the X direction, for example.

### Routing Portion 70B

Next, referring to FIG. 2 again, the routing portion 70B will be described. The routing portion 70B is a branch portion branching from the routing portion 70A. The routing portion 70B is provided over the routing portion 70A and the external connection terminals 52A and 52B, and electrically connects the routing portion 70A to the external connection terminals 52A and 52B. The routing portion 70B is a routing portion included in the sub-circuit CS of the electrical connection unit 1. The routing portion 70B is an example of a “second routing portion”.

The routing portion 70B is formed of a second number (for example, one) of metal plate portions 82 smaller than the first number. The metal plate portion 82 is a plate portion provided in the horizontal direction. The metal plate portion 82 is made of, for example, aluminum or an aluminum alloy. The plate thickness (the thickness in the Z direction) of the metal plate portion 82 is, for example, 3 mm. The plate thickness of the metal plate portion 82 is the same as the plate thickness of the metal plate portion 81 described above.

In the present embodiment, the routing portion 70B branches and extends from a part of the routing portion 70A. For example, a length L22 of the routing portion 70B in the longitudinal direction (Y direction) is twice or more a width W21 of the bus bar 54 for external connection in the Y direction (see FIG. 4). For example, a length L22 of the routing portion 70B in the longitudinal direction (Y direction) is larger than a width W11 of the electronic component 20A or the electronic component 20B in the Y direction (see FIG. 4).

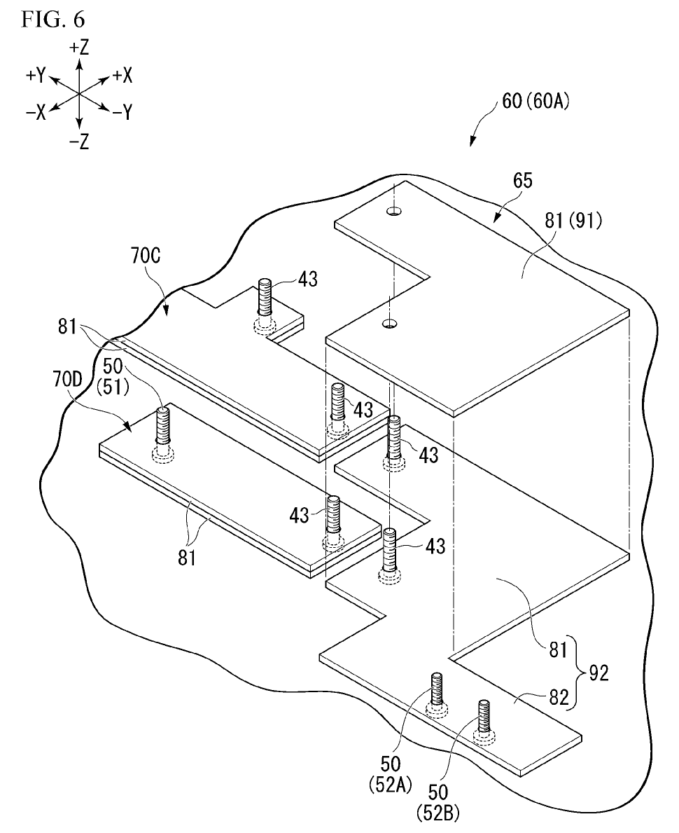

FIG. 5 is a diagram illustrating a routing structure 60A of the first structure SA. FIG. 6 is a partially exploded view illustrating the routing structure 60A of the first structure SA. In the present embodiment, the routing structure 65 includes a first metal plate 91 and a second metal plate 92. Each of the first metal plate 91 and the second metal plate 92 is a metal plate provided in the horizontal direction. The plate thickness (the thickness in the Z direction) of each of the first metal plate 91 and the second metal plate 92 is, for example, 3 mm. The first metal plate 91 and the second metal plate 92 are different in size when viewed from the Z direction.

The first metal plate 91 has an outer shape corresponding to the routing portion 70A when viewed from the Z direction. On the other hand, the second metal plate 92 has an outer shape corresponding to the routing portion 70A and the routing portion 70B when viewed from the Z direction. In the present embodiment, one metal plate portion 81 included in the routing portion 70A and one metal plate portion 82 included in the routing portion 70B are formed by one metal plate 92. That is, in the present embodiment, the first metal plate 91 having the outer shape corresponding to the routing portion 70A and the second metal plate 92 having the outer shape corresponding to the routing portion 70A and the routing portion 70B are disposed to overlap each other in the Z direction, and thus the routing structure 65 including the routing portion 70A and the routing portion 70B is formed.

### Routing Portion 70C

Next, referring to FIG. 2 again, the routing portion 70C will be described. The routing portion 70C is a routing portion connected to the electronic component 20A, the terminal 23A of the electronic component 20C, and another portion in the electrical connection unit 1. For example, the routing portion 70C is electrically connected to the terminal 23A of the electronic component 20A via the connection component 30. Note that the routing portion 70C may be directly connected to the terminal 23A of the electronic component 20A without the connection component 30 interposed therebetween.

The routing portion 70C is a routing portion included in the main circuit CM of the electrical connection unit 1. Similarly to the routing portion 70A, for example, the routing portion 70C is formed of the first number (for example, two) of metal plate portions 81 that are disposed to overlap in the Z direction. For example, in a case where the temperature rise of the routing portion 70C is limited, the routing portion 70C may be formed of the second number (for example, one) of metal plate portions 82.

### Routing Portion 70D

Next, the routing portion 70D will be described. The routing portion 70D is a routing portion that connects the electronic component 20B to the external connection terminal 51. For example, the routing portion 70D is electrically connected to the terminal 23B of the electronic component 20B via the connection component 30. Note that the routing portion 70D may be directly connected to the terminal 23B of the electronic component 20B without the connection component 30 interposed therebetween.

The routing portion 70D is a routing portion included in the main circuit CM of the electrical connection unit 1. Similarly to the routing portion 70A, for example, the routing portion 70D is formed of the first number (for example, two) of metal plate portions 81 that are disposed to overlap in the Z direction. For example, in a case where the temperature rise of the routing portion 70D is limited, the routing portion 70D may be formed of the second number (for example, one) of metal plate portions 82.

### Routing Portion 70E

Next, the routing portion 70E will be described. The routing portion 70E is a routing portion connected to the terminal 23B of the electronic component 20C. For example, the routing portion 70E is directly connected to the terminal 23B of the electronic component 20C. Note that the routing portion 70E may be connected to the terminal 23B of the electronic component 20C via the connection component 30 (for example, the connection component 30Y).

The routing portion 70E is a routing portion included in the sub-circuit CS of the electrical connection unit 1. Similarly to the routing portion 70A, for example, the routing portion 70E is formed of the first number (for example, two) of metal plate portions 81 that are disposed to overlap in the Z direction. For example, in a case where the temperature rise of the routing portion 70E is limited, the routing portion 70E may be formed of the second number (for example, one) of metal plate portions 82.

### 2.9 Cross-Sectional Structure of First Structure

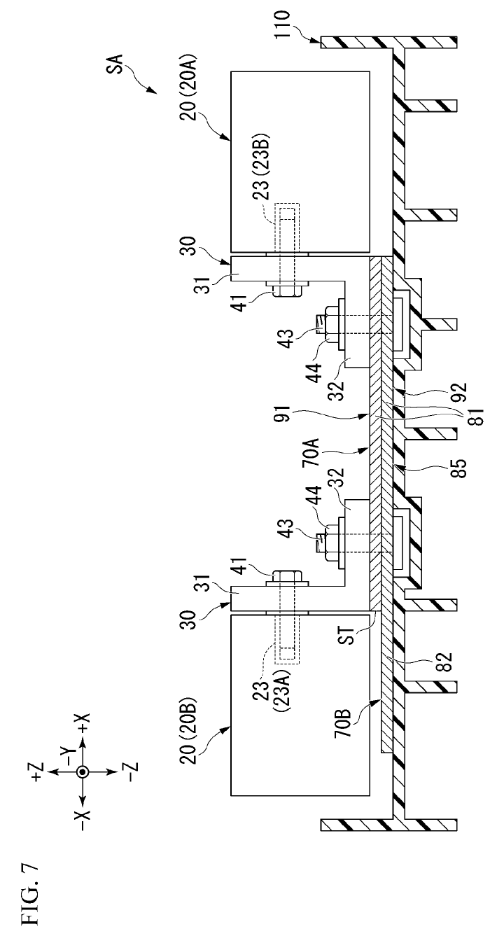

FIG. 7 is a cross-sectional view taken along line F7-F7 illustrated in FIG. 4. In the present embodiment, at the boundary between the routing portion 70A and the routing portion 70B, there is a step ST due to the difference in the number between the first number of metal plate portions 81 and the second number of metal plate portions 82. The step ST is disposed to face the side opposite to the base member 110.

In other words, the second metal plate 92 is disposed along the base member 110. The first metal plate 91 is disposed on a side opposite to the second metal plate 92 with respect to the base member 110. The base member 110 is in contact with the second metal plate 92 from below to support the second metal plate 92. The base member 110 supports the routing structure 65 by supporting the second metal plate 92.

### 2.10 Modification Example of First Structure

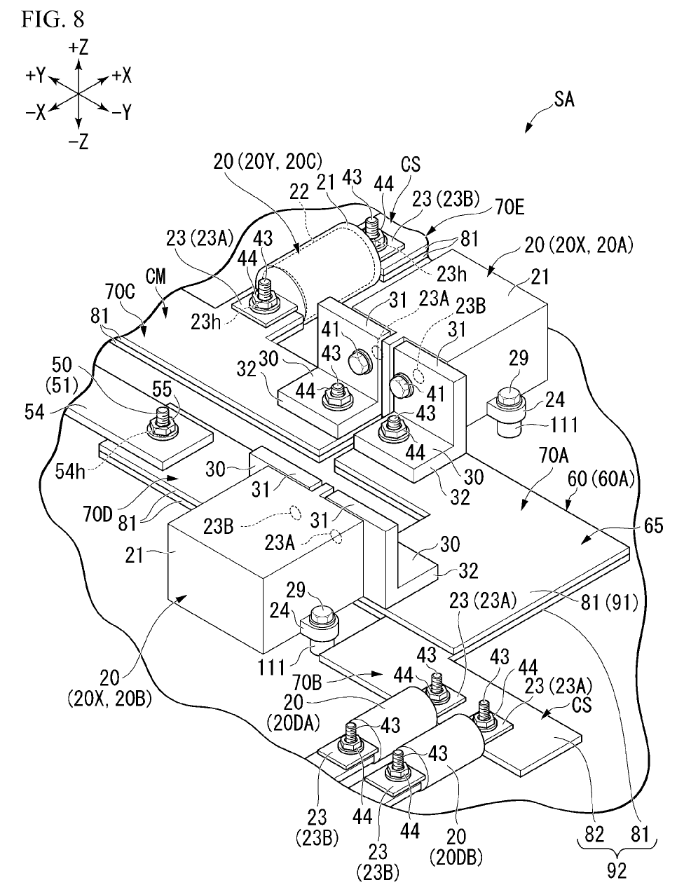

FIG. 8 is a perspective view illustrating a modification example of the first structure SA. In the present modification example, a plurality of electronic components 20 (electronic component 20DA and 20DB) are connected to the routing portion 70B. The electronic components 20DA and 20DB are, for example, fuses, sensors, or small relays. Each of the electronic components 20DA and 20DB is an electronic component that has a smaller amount of heat generation than the electronic component 20A during energization. Each of the electronic components 20DA and 20DB is an electronic component that has a smaller amount of heat generation than the electronic component 20B during energization. Each of the electronic components 20DA and 20DB may be an electronic component that has a smaller amount of heat generation than the electronic component 20C during energization. The electronic components 20DA and 20DB are components included in the sub-circuit CS of the electrical connection unit 1. The electronic component 20DA is an example of a “first component”. The electronic component 20DB is an example of a “second component”. That is, a component connected to the routing portion 70B is not limited to the external connection terminal 50, and may be an electronic component.

### 2.11 Advantages of First Structure

As a comparative example, a constitution in which each routing portion is provided with only one metal plate in the entire region of the electrical connection unit will be considered. In such a constitution of the comparative example, when an amount of heat generation of the electronic component increases, the heat dissipation capability may be insufficient, and the temperature rise of the electrical connection unit may increase. On the other hand, when each routing portion is formed of two or more metal plates in the entire region of the electrical connection unit, the cost and weight of the electrical connection unit increase.

Therefore, the electrical connection unit of the present embodiment has a first electronic component (for example, the electronic component 20A), a second electronic component (for example, the electronic component 20B), a first component (for example, the external connection terminal 52A or the electronic component 20DA), and a routing structure (for example, the routing structure 65). The first component has a smaller amount of heat generation than the first electronic component during energization. The routing structure includes a first routing portion (for example, the routing portion 70A) that electrically connects the first electronic component to the second electronic component, and a second routing portion (for example, the routing portion 70B) that electrically connects the first routing portion to the first component. The first routing portion is formed of a first number of metal plate portions (for example, the metal plate portions 81) that are disposed to overlap. The second routing portion is formed of a second number of metal plate portions (for example, the metal plate portion 82) smaller than the first number.

According to such a constitution, since the first routing portion connected to the first electronic component is formed of the first number of metal plate portions, it is possible to favorably dissipate heat of the first electronic component which is likely to have a relatively high temperature. On the other hand, since the second routing portion connected to the first component is formed of the second number of metal plate portions, the second number being smaller than the first number, the cost and weight related to the routing structure can be reduced. With this structure, the heat dissipation property of the electrical connection unit can be improved, and the cost and weight can be reduced.

In the present embodiment, one metal plate portion included in the first number of metal plate portions in the first routing portion and one metal plate portion included in the second number of metal plate portions in the second routing portion are formed of one metal plate (for example, the metal plate 92). According to such a constitution, in a constitution in which the number of metal plate portions is different between the first routing portion and the second routing portion, the number of components related to the routing structure can be reduced, and the cost and weight of the electrical connection unit can be further reduced. According to the above constitution, it is possible to realize favorable connection between the first routing portion and the second routing portion, and it is possible to improve the electrical characteristics of the electrical connection unit compared with a case where the first routing portion and the second routing portion are formed of different metal plates.

In the present embodiment, the electrical connection unit further includes a second component (for example, the external connection terminal 52B or the electronic component 20DB) that has a smaller amount of heat generation than the first electronic component during energization. The second routing portion is provided over the first routing portion, the first component, and the second component. According to such a constitution, the second routing portion is provided continuously in a certain region over the first component and the second component. In this constitution, since the second routing portion is wide, the cost and weight related to the routing structure can be further reduced.

In the present embodiment, the first routing portion includes a first connection portion (for example, the first connection portion 71) connected to the first electronic component directly or via a routing member, a second connection portion (for example, the second connection portion 72) connected to the first terminal of the second electronic component directly or via a routing member, and an extending portion (for example, the extending portion 73) extending between the first connection portion and the second connection portion. In the present embodiment, the first routing portion further includes an expansion portion (for example, the expansion portion 74) expanded from the second connection portion or the extending portion to the second side (for example, the -Y direction side). According to such a constitution, the heat capacity of the first routing portion is increased by providing the expansion portion. With this constitution, the heat dissipation property of the electrical connection unit can be further improved.

In the present embodiment, the electrical connection unit further includes a base member (for example, the base member 110) that supports the routing structure. At a boundary between the first routing portion and the second routing portion, there is a step (for example, the step ST) due to the difference in the number between the first number of metal plate portions and the second number of metal plate portions. The step is disposed to face a side opposite to the base member. According to such a constitution, even when the number of metal plate portions is different between the first routing portion and the second routing portion, a shape of the support surface of the base member that supports the routing structure can be simplified. As a result, it is possible to further reduce the cost of the electrical connection unit.

### 3. Second Structure

Next, the second structure SB will be described.

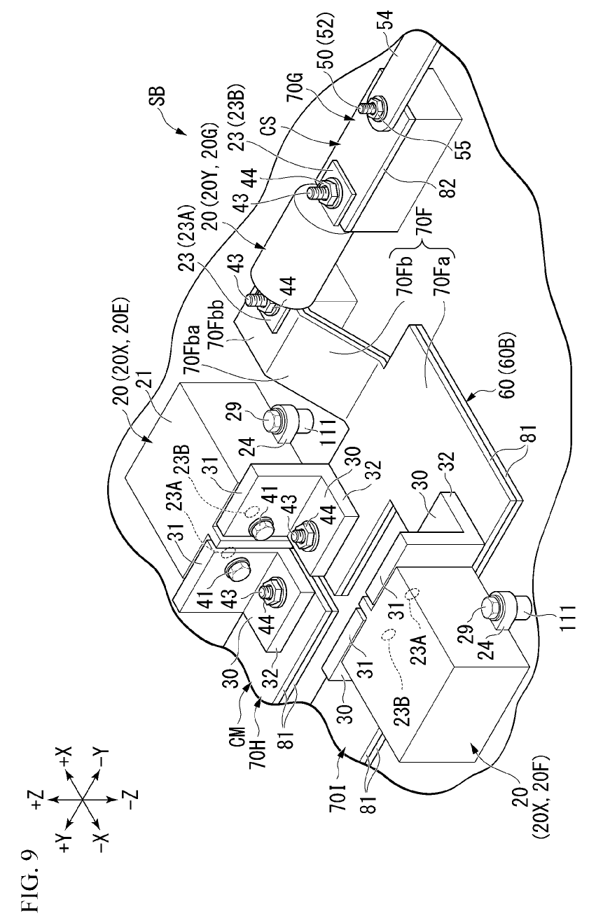

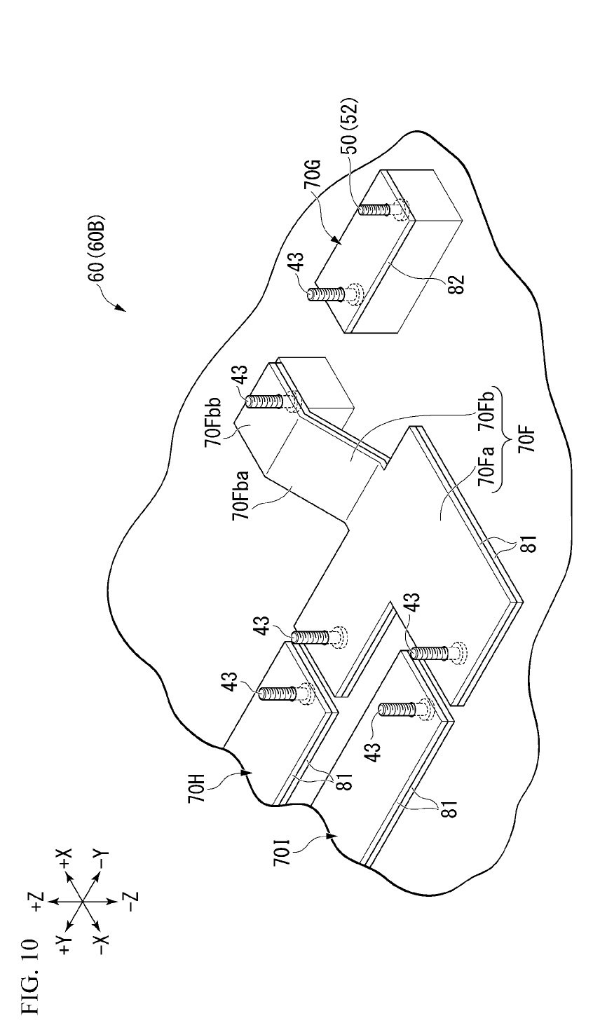

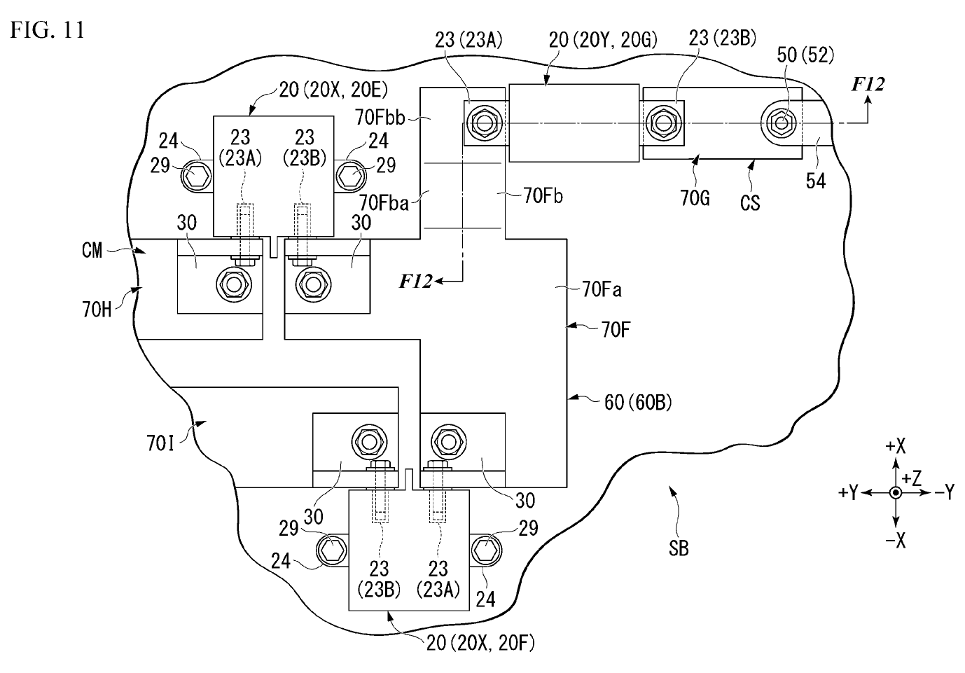

FIG. 9 is a perspective view illustrating the second structure SB. FIG. 10 is a perspective view illustrating the routing structure 60 of the second structure SB. FIG. 11 is a plan view illustrating the second structure SB. The second structure SB includes, for example, a plurality of electronic components 20, a plurality of connection components 30, an external connection terminal 50, and a routing structure 60.

### 3.1 Electronic Component of Second Structure

Next, the electronic component 20 of the second structure SB will be described. The second structure SB includes three electronic components 20E, 20F, and 20G as the plurality of electronic components 20.

Each of the electronic components 20E and 20F is, for example, a component included in the main circuit CM of the electrical connection unit 1. The electronic components 20E and 20F are electrically connected in series to each other, for example. Each of the electronic components 20E and 20F is, for example, a relay. However, the types of the electronic components 20E and 20F are not limited to the above examples. The electronic component 20E or the electronic component 20F is an example of a “first electronic component”.

On the other hand, the electronic component 20G is, for example, a component included in the sub-circuit CS of the electrical connection unit 1. The electronic component 20G is electrically connected in parallel to the electronic component 20F with respect to the electronic component 20E. The electronic component 20G is, for example, a fuse. However, the type of the electronic component 20G is not limited to the above example. The electronic component 20G has a smaller amount of heat generation than the electronic component 20E during energization. The electronic component 20G has a smaller amount of heat generation than the electronic component 20F during energization. The electronic component 20G is an example of a “second electronic component”.

### 3.2 External Connection Terminal of Second Structure

The second structure SB includes an external connection terminal 52 as the external connection terminal 50. The external connection terminal 52 is, for example, a component included in the sub-circuit CS of the electrical connection unit 1. The external connection terminal 52 is electrically connected in parallel to the electronic component 20F with respect to the electronic component 20E, for example. The external connection terminal 52 is electrically connected in series to the electronic component 20G. The external connection terminal 52 has a smaller amount of heat generation than the electronic component 20E during energization. The external connection terminal 52 has a smaller amount of heat generation than the electronic component 20F during energization. The external connection terminal 52 is an example of a “first component”.

### 3.3 Routing Structure

Next, the routing structure 60 of the second structure SB will be described.

The second structure SB has a routing structure 60B as an example of the routing structure 60. The routing structure 60B includes, for example, a routing portion 70F, a routing portion 70G, a routing portion 70H, and a routing portion 70I. The details of the metal plate portions 81 and 82 of the second structure SB are the same as the details of the metal plate portions 81 and 82 described in the first structure SA.

### Routing Portion 70F

The routing portion 70F is provided over the electronic component 20E, the electronic component 20F, and the electronic component 20G. The routing portion 70F electrically connects the electronic component 20E, the electronic component 20F, and the electronic component 20G to each other. The routing portion 70F is an example of a “first routing portion”. The routing portion 70F includes, for example, a first portion 70Fa and a second portion 70Fb.

The first portion 70Fa of the routing portion 70F is provided over the electronic component 20E and the electronic component 20F, and electrically connects the electronic component 20E to the electronic component 20F. For example, the first portion 70Fa is connected to the connection component 30 corresponding to the terminal 23B of the electronic component 20E, and is electrically connected to the terminal 23B of the electronic component 20E via the connection component 30. The first portion 70Fa is connected to the connection component 30 corresponding to the terminal 23A of the electronic component 20F, and is electrically connected to the terminal 23A of the electronic component 20F via the connection component 30. The first portion 70Fa is included in, for example, the main circuit CM of the electrical connection unit 1. Instead of the above example, the first portion 70Fa may be directly connected to the electronic components 20E and 20F without the connection component 30 interposed therebetween.

The second portion 70Fb of the routing portion 70F is a branch portion branching from the first portion 70Fa. The second portion 70Fb is provided over the first portion 70Fa and the electronic component 20G, and electrically connects the first portion 70Fa to the electronic component 20G. For example, the second portion 70Fb is directly connected to the terminal 23A of the electronic component 20G, and is electrically connected to the electronic component 20G. Note that, instead of the above example, the second portion 70Fb may be connected to the electronic component 20G via the connection component 30 (for example, the connection component 30Y). The second portion 70Fb is included in, for example, the sub-circuit CS of the electrical connection unit 1.

In the present embodiment, the second portion 70Fb of the routing portion 70F includes an inclined portion 70Fba and a flat portion 70Fbb. The inclined portion 70Fba is connected to the first portion 70Fa of the routing portion 70F. The inclined portion 70Fba extends from the first portion 70Fa of the routing portion 70F and is inclined toward the +Z direction side with respect to the horizontal direction. The flat portion 70Fbb is located on a side opposite to the first portion 70Fa of the routing portion 70F with respect to the inclined portion 70Fba. The flat portion 70Fbb is connected to the inclined portion 70Fba. In the present embodiment, the flat portion 70Fbb is directly connected to the terminal 23A of the electronic component 20G.

In the present embodiment, the entire routing portion 70F is formed of the first number (for example, two) of metal plate portions 81. That is, the first portion 70Fa and the second portion 70Fb of the routing portion 70F are formed of the first number (for example, two) of metal plate portions 81. The routing portion 70F is formed of a first number (for example, two) of metal plate portions 81 that are disposed to overlap in the Z direction. In the present embodiment, the entire routing portion 70F including the inclined portion 70Fba and the flat portion 70Fbb is formed of the first number (for example, two) of metal plate portions 81.

### Routing Portion 70G

Next, the routing portion 70G will be described. The routing portion 70G is provided over the electronic component 20G and the external connection terminal 52, and electrically connects the electronic component 20G to the external connection terminal 52. For example, the routing portion 70G is directly connected to the terminal 23B of the electronic component 20G, and is electrically connected to the electronic component 20G. Note that, instead of the above example, the routing portion 70G may be connected to the electronic component 20G via the connection component 30 (for example, the connection component 30Y). The routing portion 70G is an example of a “second routing portion”.

The routing portion 70G is a routing portion included in, for example, the sub-circuit CS of the electrical connection unit 1. The routing portion 70G is formed of the second number (for example, one) of metal plate portions 82 smaller than the first number.

### Routing Portion 70H

The routing portion 70H is a routing portion connected to the electronic component 20E and another portion in the electrical connection unit 1. For example, the routing portion 70H is connected to the connection component 30 corresponding to the terminal 23A of the electronic component 20E, and is electrically connected to the terminal 23A of the electronic component 20E via the connection component 30. The routing portion 70H is a routing portion included in, for example, the main circuit CM of the electrical connection unit 1. The routing portion 70H is formed, for example, of the first number (for example, two) of metal plate portions 81 that are disposed to overlap in the Z direction, similarly to the routing portion 70F. For example, in a case where the temperature rise of the routing portion 70H is limited, the routing portion 70H may be formed of the second number (for example, one) of metal plate portions 82.

### Routing Portion 70I

The routing portion 70I is a routing portion connected to the electronic component 20F and another portion in the electrical connection unit 1. For example, the routing portion 70I is connected to the connection component 30 corresponding to the terminal 23B of the electronic component 20F, and is electrically connected to the terminal 23B of the electronic component 20F via the connection component 30. The routing portion 70I is a routing portion included in, for example, the main circuit CM of the electrical connection unit 1. Similarly to the routing portion 70F, for example, the routing portion 70I is formed of the first number (for example, two) of metal plate portions 81 that are disposed to overlap in the Z direction. For example, in a case where the temperature rise of the routing portion 70I is limited, the routing portion 70I may be formed of the second number (for example, one) of metal plate portions 82.

### 3.4 Cross-Sectional Structure of Second Structure

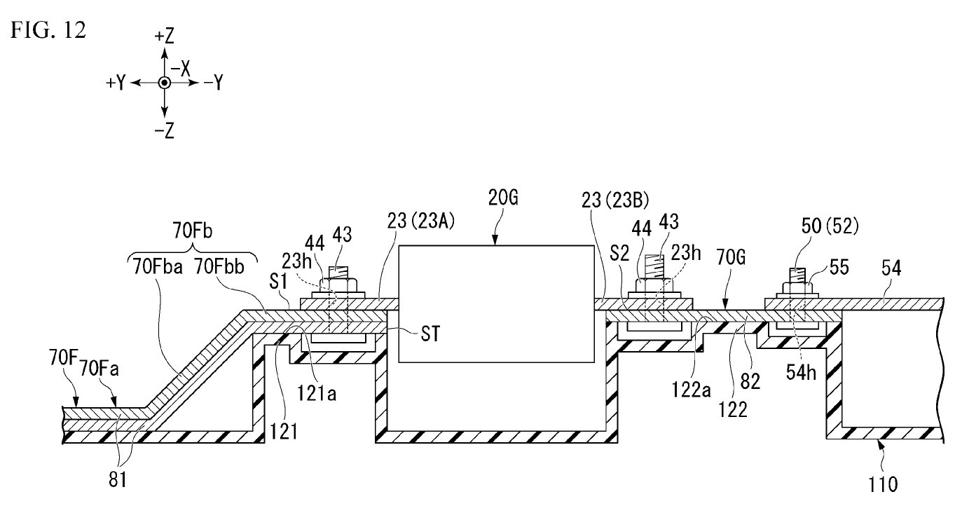

FIG. 12 is a cross-sectional view taken along line F12-F12 of the structure illustrated in FIG. 11. In the present embodiment, the routing portion 70F has a first attachment surface S1 facing the terminal 23A of the electronic component 20G. For example, the first attachment surface S1 is in contact with the terminal 23A of the electronic component 20G from below. Similarly, the routing portion 70G has a second attachment surface S2 facing the terminal 23B of the electronic component 20G. The second attachment surface S2 is in contact with the terminal 23B of the electronic component 20G from below. In the present embodiment, the first attachment surface S1 of the routing portion 70F and the second attachment surface S2 of the routing portion 70G are located on the same plane.

In the present embodiment, in the routing structure 60B, there is a step ST of the routing structure 60B due to the difference in the number between the first number of metal plate portions 81 and the second number of metal plate portions 82. The step ST is disposed downward. The base member 110 includes a first support portion 121 that supports the routing portion 70F from below and a second support portion 122 that supports the routing portion 70G from below. The first support portion 121 and the second support portion 122 are disposed at different positions (for example, different positions in the Z direction) corresponding to the difference in the number between the first number of metal plate portions 81 and the second number of metal plate portions 82. For example, an end surface 121a of the first support portion 121 on the +Z direction side is located on the -Z direction side with respect to an end surface 122a of the second support portion 122 on the +Z direction side.

### 3.5 Modification Examples of Second Structure

Next, some modification examples of the second structure SB will be described. Note that constitutions other than that described below in each modification example are the same as the constitutions of the second structure SB described above.

### 3.5.1 First Modification Example

FIG. 13 is a perspective view illustrating a first modification example of the second structure SB. In the present modification example, the routing portion 70F is connected to the terminal 23A of the electronic component 20G via the connection component 30 (for example, the connection component 30Y). The routing portion 70G is connected to the terminal 23B of the electronic component 20G via the connection component 30 (for example, the connection component 30Y).

### 3.5.2 Second Modification Example

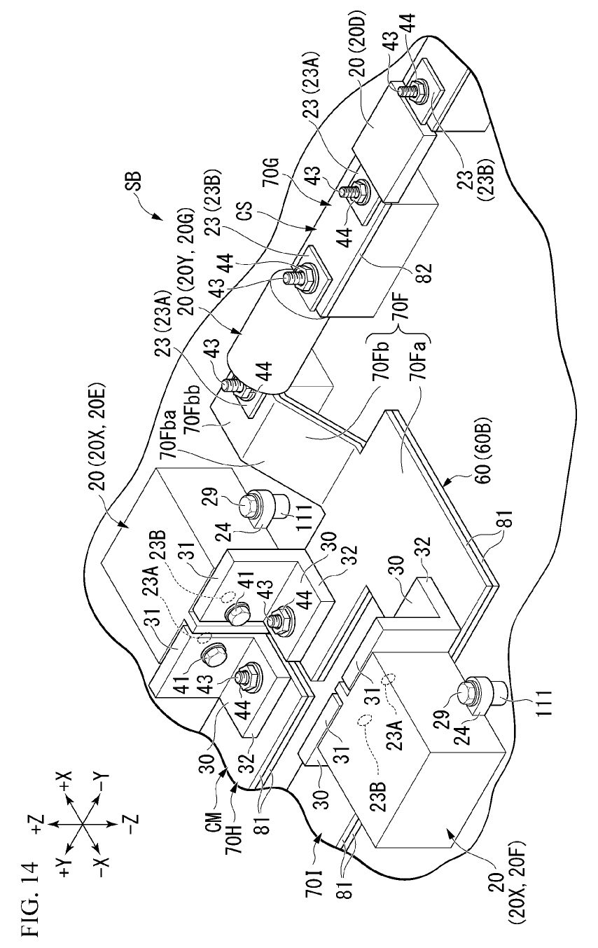

FIG. 14 is a perspective view illustrating a second modification example of the second structure SB. In the present modification example, the electronic component 20D is connected to the routing portion 70G instead of the external connection terminal 50. The electronic component 20D is, for example, a fuse, a sensor, or a small relay. The electronic component 20D is an electronic component that has a smaller amount of heat generation than the electronic component 20E during energization. The electronic component 20D is an electronic component that has a smaller amount of heat generation than the electronic component 20F during energization. The electronic component 20D is a component included in the sub-circuit CS of the electrical connection unit 1. The electronic component 20D is an example of a “first component”. That is, a component connected to the routing portion 70G is not limited to the external connection terminal 50, and may be an electronic component.

### 3.5.3 Third Modification Example

In the description of the above-described embodiment, the routing portions 70F included in the main circuit CM are formed of the first number (for example, two) of metal plate portions 81, and the routing portions 70G included in the sub-circuit CS are formed of the second number (for example, one) of metal plate portions 82. Alternatively, one routing portion 70F included in the main circuit CM may be formed of the first number (for example, two) of metal plate portions 81, and another routing portion 70G included in the main circuit CM may be formed of the second number (for example, one) of metal plate portions 82.

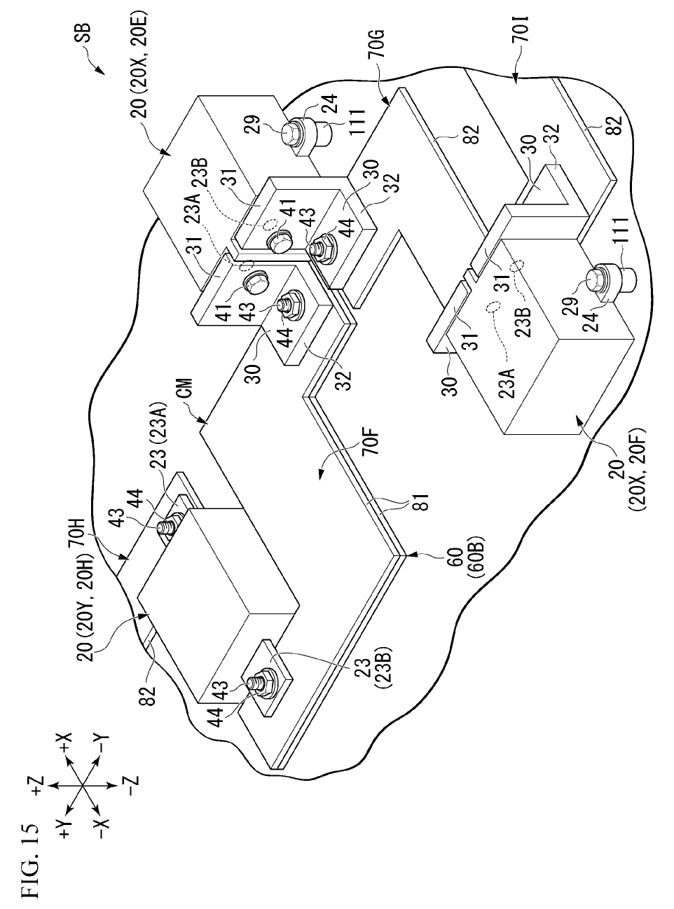

FIG. 15 is a perspective view illustrating a third modification example of the second structure SB. In the present modification example, the second structure SB includes three electronic components 20E, 20F, and 20H as the plurality of electronic components 20. The electronic components 20E, 20F, and 20H are components included in, for example, the main circuit CM of the electrical connection unit 1. The three electronic components 20E, 20F, and 20H are electrically connected in series to each other, for example.

The electronic component 20H is, for example, a large fuse. However, the type of the electronic component 20H is not limited to the above example. The electronic component 20H is an example of a “first electronic component”. Each of the electronic components 20E and 20F is a relay. However, the types of the electronic components 20E and 20F are not limited to the above examples. Each of the electronic components 20E and 20F has a smaller amount of heat generation than the electronic component 20H during energization. The electronic component 20E is an example of a “second electronic component”. The electronic component 20F is an example of each of a “first component” and a “third electronic component”.

### Routing Portion 70F

The routing portion 70F is provided over the electronic component 20H and the electronic component 20E, and is electrically connected to the electronic component 20H and the electronic component 20E. For example, the routing portion 70E is directly connected to the terminal 23B of the electronic component 20H and is electrically connected to the electronic component 20H. The routing portion 70F is connected to the connection component 30 corresponding to the terminal 23A of the electronic component 20E, and is electrically connected to the terminal 23A of the electronic component 20E via the connection component 30. Note that, instead of the above example, the routing portion 70F may be connected to the terminal 23B of the electronic component 20H via the connection component 30 (for example, the connection component 30Y). The routing portion 70F may be directly connected to the terminal 23A of the electronic component 20E without the connection component 30 interposed therebetween.

In the present modification example, the routing portion 70F is a routing portion included in the main circuit CM of the electrical connection unit 1. The routing portion 70F is formed of the first number (for example, two) of metal plate portions 81 that are disposed to overlap in the Z direction. The routing portion 70F is an example of a “first routing portion”.

### Routing Portion 70G

The routing portion 70G is provided over the electronic component 20E and the electronic component 20F, and electrically connects the electronic component 20E to the electronic component 20F. For example, the routing portion 70G is connected to the connection component 30 corresponding to the terminal 23B of the electronic component 20E, and is electrically connected to the terminal 23B of the electronic component 20E via the connection component 30. The routing portion 70G is connected to the connection component 30 corresponding to the terminal 23A of the electronic component 20F, and is electrically connected to the terminal 23A of the electronic component 20F via the connection component 30. Note that, instead of the above example, the routing portion 70G may be directly connected to the terminal 23B of the electronic component 20E and the terminal 23A of the electronic component 20F without the connection component 30 interposed therebetween.

In the present modification example, the routing portion 70G is a routing portion included in the main circuit CM of the electrical connection unit 1. In the present modification example, the routing portion 70G is formed of the second number (for example, one) of metal plate portions 82. The routing portion 70G is an example of a “second routing portion”.

### Routing Portion 70H

The routing portion 70H is a routing portion connected to the electronic component 20H and another portion in the electrical connection unit 1. For example, the routing portion 70H is directly connected to the terminal 23A of the electronic component 20H. Instead of the above example, the routing portion 70H may be connected to the terminal 23A of the electronic component 20H via the connection component 30 (for example, the connection component 30Y). The routing portion 70G is a routing portion included in the main circuit CM of the electrical connection unit 1. Similarly to the routing portion 70G, for example, the routing portion 70H is formed of the second number (for example, one) of metal plate portions 82. For example, in a case where the temperature rise of the routing portion 70H is large, the routing portion 70H may be formed of the first number (for example, two) of metal plate portions 81 that are disposed to overlap in the Z direction.

### Routing Portion 70I

The routing portion 70I is a routing portion connected to the electronic component 20F and another portion in the electrical connection unit 1. For example, the routing portion 70I is connected to the connection component 30 corresponding to the terminal 23B of the electronic component 20F, and is electrically connected to the terminal 23B of the electronic component 20F via the connection component 30. Instead of the above example, the routing portion 70I may be connected to the terminal 23B of the electronic component 20F without the connection component 30 interposed therebetween. Similarly to the routing portion 70G, for example, the routing portion 70I is formed of the second number (for example, one) of metal plate portions 82. For example, in a case where the temperature rise of the routing portion 70I is large, the routing portion 70I may be formed of the first number (for example, two) of metal plate portions 81 that are disposed to overlap in the Z direction.

### 3.6 Advantages of Second Structure

As a comparative example, a constitution in which each routing portion is provided with only one metal plate in the entire region of the electrical connection unit will be considered. In such a constitution of the comparative example, when an amount of heat generation of the electronic component increases, the heat dissipation capability may be insufficient, and the temperature rise of the electrical connection unit may increase. On the other hand, when each routing portion is formed of two or more metal plates in the entire region of the electrical connection unit, the cost and weight of the electrical connection unit increase.

Therefore, the electrical connection unit of the present embodiment includes a first electronic component (for example, the electronic component 20E or the electronic component 20H), a second electronic component (for example, the electronic component 20G or the electronic component 20E), a first routing portion (for example, the routing portion 70F), and a second routing portion (the routing portion 70G). The second electronic component has a first terminal (for example, the terminal 23A) and a second terminal (for example, the terminal 23B). The second electronic component has a smaller amount of heat generation than the first electronic component during energization. The first routing portion is connected to the first terminal of the second electronic component directly or via a routing member, and electrically connects the first electronic component to the second electronic component. The second routing portion is connected to the second terminal of the second electronic component directly or via a routing member. The first routing portion is formed of a first number of metal plate portions (for example, the metal plate portions 81) that are disposed to overlap. The second routing portion is formed of a second number of metal plate portions (for example, the metal plate portion 82) smaller than the first number.

According to such a constitution, since the first routing portion provided between the first electronic component and the second electronic component is formed of the first number of metal plate portions, it is possible to favorably dissipate heat of the first electronic component which is likely to have a relatively high temperature. On the other hand, since the second routing portion that is less likely to be affected by heat from the first electronic component than the first routing portion is formed of the second number of metal plate portions, the second number being smaller than the first number, the cost and weight related to the routing structure can be reduced. With this structure, the heat dissipation property of the electrical connection unit can be improved, and the cost and weight can be reduced.

In the present embodiment, the first routing portion has a first attachment surface (for example, the first attachment surface S1) facing the first terminal or a routing member (for example, the connection component 30) connected to the first terminal. The second routing portion has a second attachment surface (for example, the second attachment surface S2) facing the second terminal or a routing member (for example, the connection component 30) connected to the second terminal. The first attachment surface and the second attachment surface are located on the same plane. According to such a constitution, even in a case where the number of metal plate portions is different between the first routing portion and the second routing portion, since the two attachment surfaces facing the terminal of the electronic component or the routing member (for example, the connection component 30) are located on the same plane, it becomes easier to attach an electronic component. As a result, it is possible to further reduce the cost of the electrical connection unit.

In the present embodiment, the electrical connection unit further includes a base member (for example, the base member 110) that supports the first routing portion and the second routing portion. The base member includes a first support portion (for example, the first support portion 121) that supports the first routing portion and a second support portion (for example, the second support portion 122) that supports the second routing portion. The first support portion and the second support portion are provided at different positions corresponding to a difference in the number between the first number of metal plate portions and the second number of metal plate portions. According to such a constitution, even in a case where the number of metal plate portions is different between the first routing portion and the second routing portion, it is possible to stably support the first routing portion and the second routing portion since positions of the first support portion and the second support portion are different. As a result, durability of the electrical connection unit can be enhanced.

According to still another aspect, the above-described second structure SB can be described as follows. The second structure SB includes a first electronic component (for example, the electronic component 20E or the electronic component 20H), a second electronic component (for example, the electronic component 20G or the electronic component 20E), a first component (for example, the external connection terminal 50, the electronic component 20D, or the electronic component 20F), a first routing portion (for example, the routing portion 70F), and a second routing portion (for example, the routing portion 70G). The second electronic component has a first terminal (for example, the terminal 23A) and a second terminal (for example, the terminal 23B). The first component has a smaller amount of heat generation than the first electronic component during energization. The first routing portion is connected to the first terminal of the second electronic component, and electrically connects the first electronic component to the second electronic component. The second routing portion is connected to the second terminal of the second electronic component, and electrically connects the second electronic component to the first component. The first routing portion is formed of the first number of metal plate portions (for example, the metal plate portions 81) that are disposed to overlap in the Z direction. The second routing portion is formed of the second number of metal plate portions (for example, the metal plate portion 82).

According to such a constitution, since the first routing portion provided between the first electronic component and the second electronic component is formed of the first number of metal plate portions, it is possible to favorably dissipate heat of the first electronic component which is likely to have a relatively high temperature. On the other hand, since the second routing portion provided between the second electronic component and the first component is formed of the second number of metal plate portions, the second number being smaller than the first number, the cost and weight related to the routing structure can be reduced. With this structure, the heat dissipation property of the electrical connection unit can be improved, and the cost and weight can be reduced.

In the above relationship, the second electronic component (the electronic component 20G or the electronic component 20E) is not limited to an electronic component that has a smaller amount of heat generation than the first electronic component (the electronic component 20E, the electronic component 20F, or the electronic component 20H) during energization. The second electronic component (the electronic component 20G or the electronic component 20E) may be an electronic component that has an amount of heat generation equal to or greater than that of the first electronic component (the electronic component 20E, the electronic component 20F, or the electronic component 20) during energization.

According to still another aspect, for example, the second modification example can be described as follows. The second structure SB includes a first electronic component (for example, the electronic component 20E), a second electronic component (for example, the electronic component 20F), a third electronic component (for example, the electronic component 20G), a fourth electronic component (for example, the electronic component 20D), a first routing portion (for example, the routing portion 70F), and a second routing portion (for example, the routing portion 70G). The third electronic component has a smaller amount of heat generation than the first electronic component during energization. The first routing portion electrically connects the first electronic component to the second electronic component. The second routing portion electrically connects the third electronic component to the fourth electronic component. The first routing portion is formed of the first number of metal plate portions (for example, the metal plate portions 81) that are disposed to overlap in the Z direction. The second routing portion is formed of the second number of metal plate portions (for example, the metal plate portion 82).

According to such a constitution, since the first routing portion provided between the first electronic component and the second electronic component is formed of the first number of metal plate portions, it is possible to favorably dissipate heat of the first electronic component which is likely to have a relatively high temperature. On the other hand, since the second routing portion provided between the third electronic component and the fourth electronic component is formed of the second number of metal plate portions, the second number being smaller than the first number, the cost and weight related to the routing structure can be reduced. With this structure, the heat dissipation property of the electrical connection unit can be improved, and the cost and weight can be reduced.

### 4. Third Structure

Next, the third structure SC will be described.

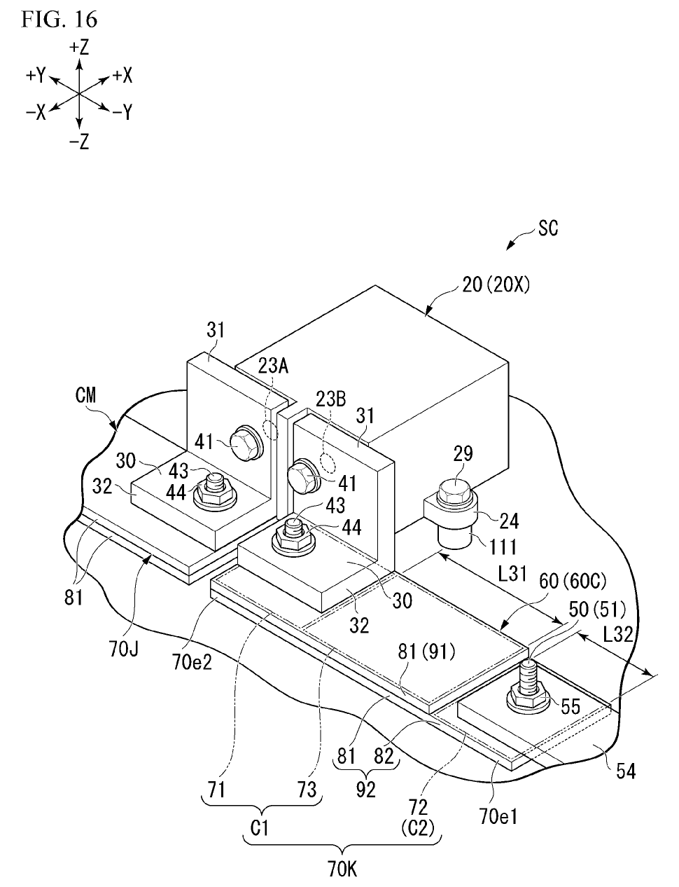

FIG. 16 is a perspective view illustrating third structure SC. The third structure SC includes, for example, an electronic component 20, a plurality of connection components 30, an external connection terminal 50, and a routing structure 60.

### 4.1 Electronic Component of Third Structure

The electronic component 20 is, for example, a component included in the main circuit CM of the electrical connection unit 1. The electronic component 20 is, for example, a relay. The type of the electronic component 20 is not limited to the above example. The electronic component 20 may be a component included in the sub-circuit CS of the electrical connection unit 1.

### 4.2 External Connection Terminal of Third Structure

The external connection terminal 50 is, for example, an external connection terminal 51 included in the main circuit CM of the electrical connection unit 1. The external connection terminal 50 may be the external connection terminal 52 included in the sub-circuit CS of the electrical connection unit 1.

### 4.3 Routing Structure

Next, the routing structure 60 of the third structure SC will be described.

The third structure SC has a routing structure 60C as an example of the routing structure 60. The routing structure 60C includes, for example, a routing portion 70J and a routing portion 70K. The details of the metal plate portions 81 and 82 of the third structure SC are the same as the details of the metal plate portions 81 and 82 described in the first structure SA.

### Routing Portion 70J

The routing portion 70J is provided over the electronic component 20 and another portion in the electrical connection unit 1. The routing portion 70J is connected to the connection component 30 corresponding to the terminal 23A of the electronic component 20, and is electrically connected to the terminal 23A of the electronic component 20 via the connection component 30. Note that the routing portion 70J may be directly connected to the terminal 23A of the electronic component 20 without the connection component 30 interposed therebetween. The routing portion 70J is formed of the first number (for example, two) of metal plate portions 81 that are disposed to overlap in the Z direction.

### Routing Portion 70K

The routing portion 70K is provided over the electronic component 20 and the external connection terminal 50. The routing portion 70K is connected to the connection component 30 corresponding to the terminal 23B of the electronic component 20, and is electrically connected to the terminal 23B of the electronic component 20 via the connection component 30. Note that the routing portion 70K may be directly connected to the terminal 23B of the electronic component 20 without the connection component 30 interposed therebetween. The routing portion 70K includes, for example, a first connection portion 71, a second connection portion 72, and an extending portion 73.

The first connection portion 71 is located at an end portion 70e2 of the routing portion 70K. The end portion 70e2 is an example of a “second end portion”. The first connection portion 71 overlaps the connection component 30 when viewed from the Z direction. The first connection portion 71 is connected to the connection component 30 and is electrically connected to the electronic component 20 via the connection component 30. Note that the first connection portion 71 may be directly connected to the terminal 23B of the electronic component 20 without the connection component 30 interposed therebetween.

The second connection portion 72 is located at an end portion 70e1 of the routing portion 70K. The end portion 70e1 is an end portion opposite to the end portion 70e2. The end portion 70e1 is an example of a “first end portion”. The second connection portion 72 is provided with an external connection terminal 50. The second connection portion 72 overlaps the bus bar 54 for external connection attached to the external connection terminal 50 when viewed from the Z direction. The second connection portion 72 is electrically connected to the bus bar 54 for external connection via the external connection terminal 50.

The extending portion 73 extends between the first connection portion 71 and the second connection portion 72. The extending portion 73 extends between the end portion 70e1 and the end portion 70e2. The extending portion 73 extends in the X direction or the Y direction. A length L31 of the extending portion 73 in the longitudinal direction (for example, the Y direction) of the routing portion 70K is larger than, for example, a length L32 of the second connection portion 72 in the longitudinal direction (for example, the Y direction) of the routing portion 70K.

In the present embodiment, the routing portion 70K includes a first portion C1 and a second portion C2. The first portion C1 includes the first connection portion 71 and the extending portion 73. In other words, the first portion C1 includes the end portion 70e2 and the extending portion 73. On the other hand, the second portion C2 includes the second connection portion 72. In other words, the second portion C2 includes the end portion 70e1.

In the present embodiment, the first portion C1 is formed of the first number (for example, two) of metal plate portions 81 that are disposed to overlap in the Z direction. On the other hand, the second portion C2 is formed of the second number (for example, one) of metal plate portions 82.

In the present embodiment, the routing portion 70K includes a first metal plate 91 and a second metal plate 92. Each of the first metal plate 91 and the second metal plate 92 is a metal plate provided in the horizontal direction. The plate thickness (the thickness in the Z direction) of each of the first metal plate 91 and the second metal plate 92 is, for example, 3 mm. The first metal plate 91 and the second metal plate 92 are different in size when viewed from the Z direction.

The first metal plate 91 has an outer shape corresponding to the first portion C1 of the routing portion 70K when viewed from the Z direction. On the other hand, the second metal plate 92 has an outer shape corresponding to the entire routing portion 70K (for example, the first portion C1 and the second portion C2) when viewed from the Z direction. In the present embodiment, one metal plate portion 81 included in the first portion C1 and one metal plate portion 82 included in the second portion C2 are formed by one metal plate 92. That is, in the present embodiment, the first metal plate 91 having the outer shape corresponding to the first portion C1 of the routing portion 70K and the second metal plate 92 having the outer shape corresponding to the entire routing portion 70K are disposed to overlap each other in the Z direction, thereby forming the routing portion 70K.

### 4.4 Cross-Sectional Structure of Third Structure

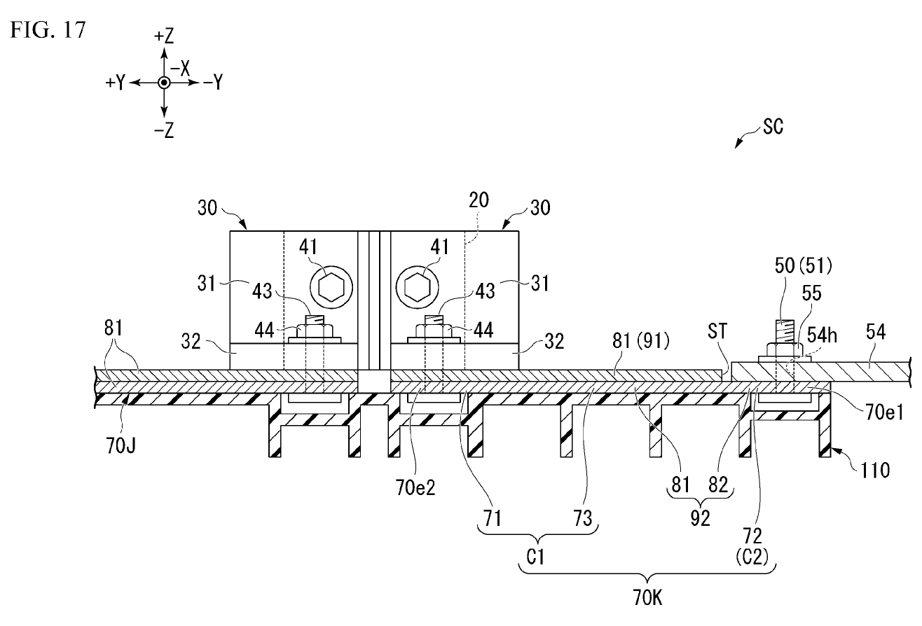

FIG. 17 is a cross-sectional view illustrating the third structure SC. In the present embodiment, at the boundary between the first portion C1 and the second portion C2 of the routing portion 70K, there is a step ST due to the difference in the number between the first number of metal plate portions 81 and the second number of metal plate portions 82. The step ST is disposed to face the side opposite to the base member 110.

In other words, the second metal plate 92 is disposed along the base member 110. The first metal plate 91 is disposed on a side opposite to the second metal plate 92 with respect to the base member 110. The base member 110 is in contact with the second metal plate 92 from below to support the second metal plate 92. The base member 110 supports the routing portion 70K by supporting the second metal plate 92.

### 4.5 Modification Example of Third Structure

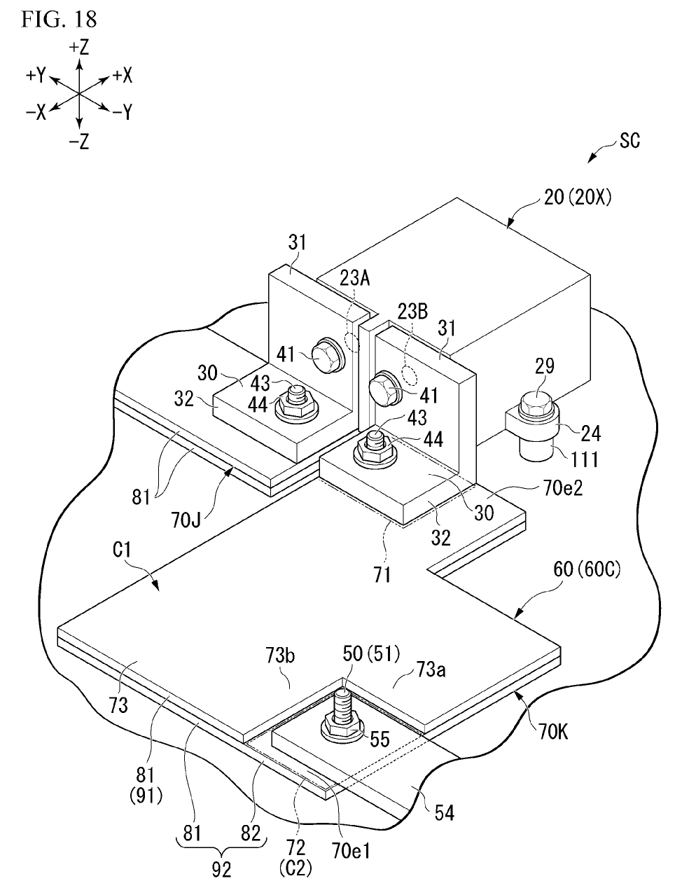

FIG. 18 is a perspective view illustrating a modification example of the third structure SC. In the present modification example, the routing portion 70K has a flat plate shape spreading in the X direction and the Y direction. The extending portion 73 of the routing portion 70K includes a first portion 73a adjacent to the external connection terminal 50 in the X direction and a second portion 73b adjacent to the external connection terminal 50 in the Y direction. In the present modification example, the first portion 73a and the second portion 73b of the extending portion 73 are formed of the first number (for example, two) of metal plate portions 81 that are disposed to overlap in the Z direction.

### 4.6 Advantages of Third Structure

In a case where the routing portion is formed of two metal plates that overlap each other, the axial force loss in the fixing structure for fixing the routing member for external connection increases compared with a case where the routing portion is formed of one metal plate. In a case where the axial force loss increases, it is necessary to increase the size of the fixing structure for fixing the routing member for external connection, and it is necessary to change the dimension related to the routing member for external connection.

On the other hand, the electrical connection unit of the present embodiment includes an external connection terminal (for example, the external connection terminal 50) and a routing portion (for example, the routing portion 70K). A routing member for external connection can be attached to the external connection terminal. The routing portion includes a first portion (for example, the first portion C1) and a first end portion (for example, the end portion 70e1) provided with the external connection terminal. The first portion is formed of the first number of metal plate portions (for example, metal plate portions 81) that are disposed to overlap. The first end portion is formed of the second number of metal plate portions (for example, the metal plate portion 82) smaller than the first number.

According to such a constitution, since a part of the routing portion is formed of the first number of metal plate portions, the heat capacity of the routing portion increases, and the heat dissipation property of the electrical connection unit can be enhanced. On the other hand, since the first end portion of the routing portion is formed of the second number of metal plate portions, the second number being smaller than the first number, it is possible to suppress an increase in size due to an axial force loss of the fixing structure for fixing the routing member for external connection. With this structure, the heat dissipation property of the electrical connection unit can be improved, and the size thereof can be reduced.

In the present embodiment, the first portion of the routing portion includes a second end portion (for example, the end portion 70e2) connected to an electronic component (for example, the electronic component 20) directly or via a routing member (for example, the connection component 30), and an extending portion (for example, the extending portion 73) extending between the first end portion and the second end portion. Each of the second end portion and the extending portion is formed of the first number of metal plate portions that are disposed to overlap. According to such a constitution, in addition to the second end portion, the extending portion is formed of the first number of metal plate portions that are disposed to overlap, so that the heat capacity of the routing portion can be further increased. With this constitution, the heat dissipation property of the electrical connection unit can be further enhanced.

In the present embodiment, one metal plate portion included in the first number of metal plate portions in the first portion and one metal plate portion included in the second number of metal plate portions in the first end portion are formed of one metal plate (for example, the metal plate 92). According to such a constitution, in a constitution in which the number of metal plate portions is different between the first portion and the first end portion, the number of components related to the routing structure can be reduced, and the cost and weight of the electrical connection unit can be further reduced. According to the above constitution, it is possible to realize favorable connection between the first portion and the first end portion, and it is possible to improve the electrical characteristics of the electrical connection unit compared with a case where the first portion and the first end portion are formed of different metal plates.

In the present embodiment, the electrical connection unit further includes a base member (for example, the base member 110) that supports the routing portion. At the boundary between the first portion and the first end portion, there is a step (for example, a step ST) due to the difference in the number between the first number of metal plate portions and the second number of metal plate portions. The step is disposed to face a side opposite to the base member. According to such a constitution, even in a case where the number of metal plate portions is different between the first portion and the first end portion, the shape of the support surface of the base member that supports the routing portion can be simplified. As a result, it is possible to further reduce the cost of the electrical connection unit.

### 5. Fourth Structure

Next, the fourth structure SD will be described.

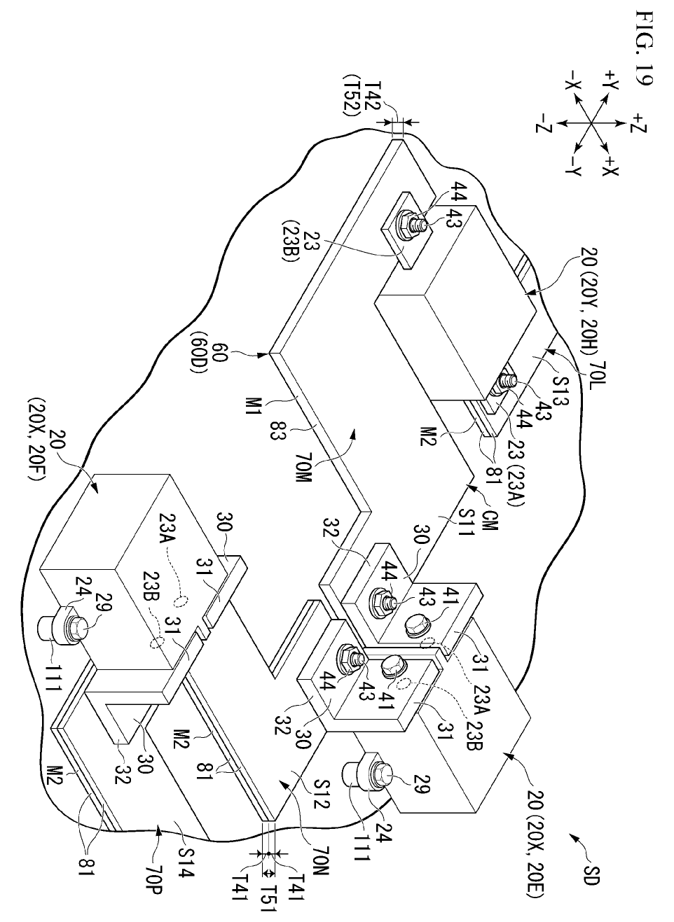

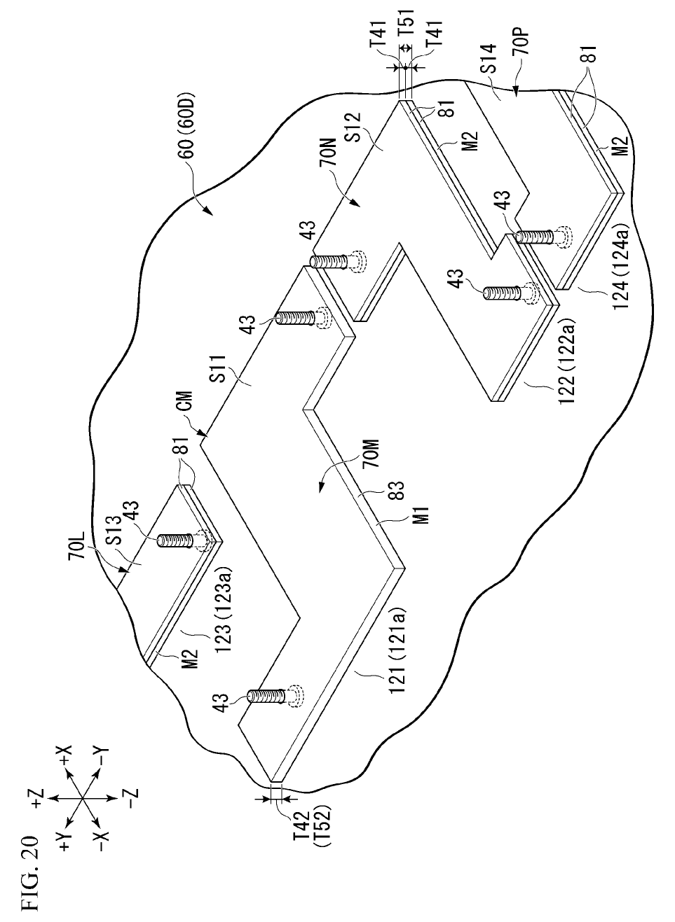

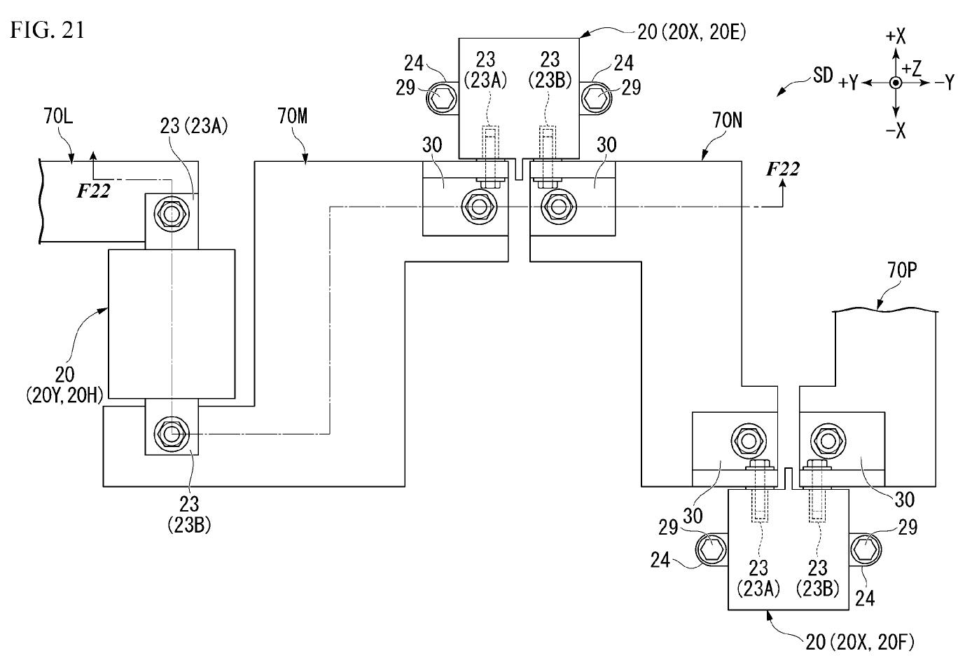

FIG. 19 is a perspective view illustrating the fourth structure SD. FIG. 20 is a perspective view illustrating the routing structure 60 of the fourth structure SD. FIG. 21 is a plan view illustrating the fourth structure SD. The fourth structure SD includes, for example, a plurality of electronic components 20, a plurality of connection components 30, and a routing structure 60.

### 5.1 Electronic Component

The fourth structure SD includes three electronic components 20E, 20F, and 20H as the plurality of electronic components 20. The electronic components 20E, 20F, and 20H are components included in, for example, the main circuit CM of the electrical connection unit 1. The three electronic components 20E, 20F, and 20H are electrically connected in series to each other, for example.

The electronic component 20H is, for example, a large fuse. However, the type of the electronic component 20H is not limited to the above example. The electronic component 20H is an example of a “first electronic component”. Each of the electronic components 20E and 20F is a relay. However, the types of the electronic components 20E and 20F are not limited to the above examples. Each of the electronic components 20E and 20F has a smaller amount of heat generation than the electronic component 20H during energization. The electronic component 20E is an example of a “second electronic component”. The electronic component 20F is an example of each of a “first component” and a “third electronic component”. The fourth structure SD may include an external connection terminal 50 as the first component instead of the electronic component 20F.

### 5.2 Routing Structure

The fourth structure SD includes a routing structure 60D as the routing structure 60. The routing structure 60D includes a routing portion 70L, a routing portion 70M, a routing portion 70N, and a routing portion 70P.

### Routing Portion 70L

The routing portion 70L is a routing portion connected to the electronic component 20H and another portion of the electrical connection unit 1. For example, the routing portion 70L is directly connected to the terminal 23A of the electronic component 20H and is electrically connected to the electronic component 20H. Note that the routing portion 70L may be connected to the terminal 23A of the electronic component 20H via the connection component 30 (for example, the connection component 30Y) and electrically connected to the electronic component 20H.

### Routing Portion 70M

The routing portion 70M is provided over the electronic component 20H and the electronic component 20E, and electrically connects the electronic component 20H to the electronic component 20E. For example, the routing portion 70M is directly connected to the terminal 23B of the electronic component 20H and is electrically connected to the electronic component 20H. The routing portion 70M is connected to the connection component 30 corresponding to the terminal 23A of the electronic component 20E, and is electrically connected to the terminal 23A of the electronic component 20E via the connection component 30. Note that, instead of the above example, the routing portion 70M may be connected to the terminal 23B of the electronic component 20H via the connection component 30. The routing portion 70M may be directly connected to the terminal 23A of the electronic component 20E without the connection component 30 interposed therebetween. The routing portion 70M is an example of a “first routing portion”.

### Routing Portion 70N

The routing portion 70N is provided over the electronic component 20E and the electronic component 20F, and electrically connects the electronic component 20E to the electronic component 20F. For example, the routing portion 70N is connected to the connection component 30 corresponding to the terminal 23B of the electronic component 20E, and is electrically connected to the terminal 23B of the electronic component 20E via the connection component 30. The routing portion 70N is connected to the connection component 30 corresponding to the terminal 23A of the electronic component 20F, and is electrically connected to the terminal 23A of the electronic component 20F via the connection component 30. Note that, instead of the above example, the routing portion 70N may be directly connected to the terminal 23B of the electronic component 20E. The routing portion 70N may be directly connected to the terminal 23A of the electronic component 20F. The routing portion 70N is an example of a “second routing portion”.

### Routing Portion 70P

The routing portion 70P is a routing portion connected to the electronic component 20F and another portion of the electrical connection unit 1. For example, the routing portion 70P is connected to the connection component 30 corresponding to the terminal 23B of the electronic component 20F, and is electrically connected to the terminal 23B of the electronic component 20F via the connection component 30. Note that the routing portion 70P may be directly connected to the terminal 23B of the electronic component 20F.

### 5.3 Material and Thickness of Routing Structure

In the present embodiment, the routing portion 70M is formed of at least one metal plate portion 83. In the present embodiment, the routing portion 70M is formed by one metal plate portion 83. However, the routing portion 70M may be formed of two or more metal plate portions 83 that are disposed to overlap in the Z direction. The metal plate portion 83 is a plate portion provided in the horizontal direction. The metal plate portion 83 contains a first material M1. The first material M1 is a material having a higher thermal conductivity than a second material M2 that will be described later. The first material M1 is, for example, copper or a copper alloy. A plate thickness (the thickness in the Z direction) T42 of the metal plate portion 83 is, for example, 5 mm. The metal plate portion 83 is an example of a “first metal plate portion”.

On the other hand, each of the routing portion 70L, the routing portion 70N, and the routing portion 70P is formed of a plurality of (for example, two) metal plate portions 81 that are disposed to overlap in the Z direction. The metal plate portion 81 is a plate portion provided in the horizontal direction. The metal plate portion 81 contains the second material M2. The second material M2 is, for example, aluminum or an aluminum alloy. A plate thickness (the thickness in the Z direction) T41 of the metal plate portion 81 is, for example, 3 mm. The metal plate portion 81 is an example of a “second metal plate portion”.

In the present embodiment, the number of metal plate portions 83 is smaller than the number of metal plate portions 81. However, the number of metal plate portions 83 may be the same as or larger than the number of the metal plate portions 81.

In the present embodiment, the total thickness T52 (for example, 5 mm) of the at least one metal plate portion 83 in the Z direction is smaller than the total thickness T51 (for example, 6 mm) of the plurality of metal plate portions 81 in the Z direction. In other words, the thickness of the routing portion 70M in the Z direction is smaller than the thickness of each of the routing portion 70L, the routing portion 70N, and the routing portion 70P in the Z direction.

On the other hand, the thickness T42 (for example, 5 mm) of the single metal plate portion 83 in the Z direction is larger than the thickness T41 (for example, 3 mm) of the single metal plate portion 81 in the Z direction.

### 5.4 Cross-Sectional Structure of Fourth Structure

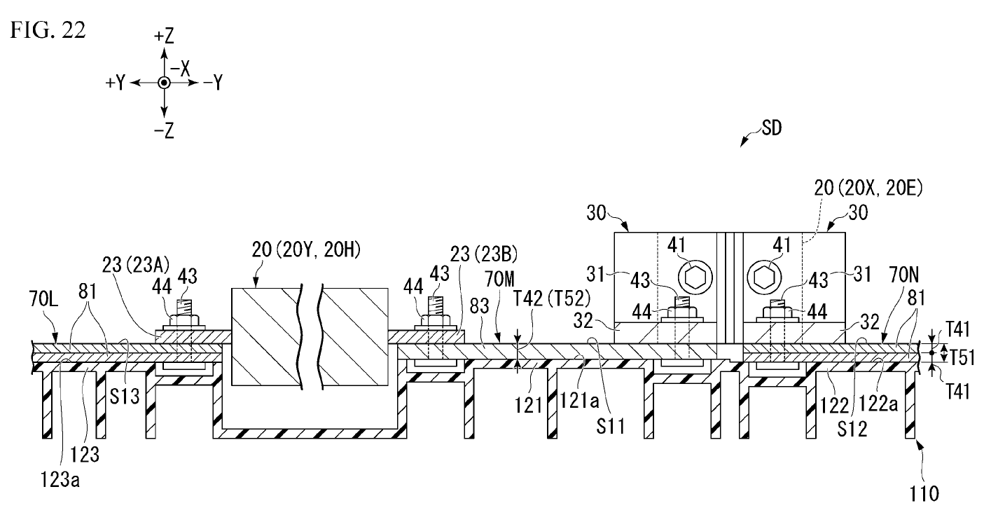

FIG. 22 is a cross-sectional view taken along line F22-F22 of the structure illustrated in FIG. 21. In the present embodiment, the routing portion 70M has a first attachment surface S11. The first attachment surface S11 faces the terminal 23B of the electronic component 20H from below, and faces the connection component 30 corresponding to the terminal 23A of the electronic component 20E from below. For example, the first attachment surface S11 is in contact with the terminal 23B of the electronic component 20H from below, and is in contact with the connection component 30 corresponding to the terminal 23A of the electronic component 20E from below. Note that the first attachment surface S11 may be a surface in contact with the connection component 30 corresponding to the terminal 23B of the electronic component 20H from below, or may be a surface in contact with the terminal 23A of the electronic component 20E from below.

The routing portion 70N has a second attachment surface S12. The second attachment surface S12 faces the connection component 30 corresponding to the terminal 23B of the electronic component 20E from below, and faces the connection component 30 corresponding to the terminal 23A of the electronic component 20F from below. For example, the second attachment surface S12 is in contact with the connection component 30 corresponding to the terminal 23B of the electronic component 20E from below, and is in contact with the connection component 30 corresponding to the terminal 23A of the electronic component 20F from below. The second attachment surface S12 may be a surface in contact with the terminal 23B of the electronic component 20E from below, or may be a surface in contact with the terminal 23A of the electronic component 20F from below.

The routing portion 70L has a third attachment surface S13. The third attachment surface S13 faces the terminal 23A of the electronic component 20H from below. For example, the third attachment surface S13 is in contact with the terminal 23A of the electronic component 20H from below. The third attachment surface S13 may be a surface in contact with the connection component 30 corresponding to the terminal 23A of the electronic component 20H from below.

The routing portion 70P has a fourth attachment surface S14 (see FIG. 19). The fourth attachment surface S14 faces the connection component 30 corresponding to the terminal 23B of the electronic component 20F from below. For example, the fourth attachment surface S14 is in contact with the connection component 30 corresponding to the terminal 23B of the electronic component 20F from below. The fourth attachment surface S14 may be a surface in contact with the terminal 23B of the electronic component 20F from below.

In the present embodiment, the first attachment surface S11 of the routing portion 70M, the second attachment surface S12 of the routing portion 70N, the third attachment surface S13 of the routing portion 70L, and the fourth attachment surface S14 of the routing portion 70P are located on the same plane.

In the present embodiment, the base member 110 includes a first support portion 121, a second support portion 122, a third support portion 123, and a fourth support portion 124 (see FIG. 20). The first support portion 121 supports the routing portion 70M from below. The second support portion 122 supports the routing portion 70N from below. The third support portion 123 supports the routing portion 70L from below. The fourth support portion 124 supports the routing portion 70P from below.

In the present embodiment, the first support portion 121, the second support portion 122, the third support portion 123, and the fourth support portion 124 are provided at different positions corresponding to the difference between the thickness of the routing portion 70M in the Z direction and the thickness of each of the routing portion 70L, the routing portion 70M, and the routing portion 70P in the Z direction. For example, the respective end surfaces 122a, 123a, and 124a of the second support portion 122, the third support portion 123, and the fourth support portion 124 on +Z direction side are located on the -Z direction side with respect to the end surface 121a of the first support portion 121 on +Z direction side.

### 5.5 Advantages of Fourth Structure

As a comparative example, a constitution in which each routing portion is formed of two metal plates made of a specific material and disposed to overlap in the entire region of the electrical connection unit will be considered. In such a constitution of the comparative example, when an amount of heat generation of the electronic component increases, the heat dissipation capability may be insufficient, and the temperature rise of the electrical connection unit may increase.

Therefore, the electrical connection unit of the present embodiment includes a first electronic component (for example, the electronic component 20H), a second electronic component (for example, the electronic component 20E), a first routing portion (for example, the routing portion 70M), and a second routing portion (for example, the routing portion 70N). The second electronic component has a first terminal (for example, the terminal 23A) and a second terminal (for example, the terminal 23B). The second electronic component has a smaller amount of heat generation than the first electronic component during energization. The first routing portion is connected to the first terminal of the second electronic component directly or via a routing member, and electrically connects the first electronic component to the second electronic component. The second routing portion is connected to the second terminal of the second electronic component directly or via a routing member. The first routing portion is formed of at least one first metal plate portion (for example, the metal plate portion 83). The second routing portion is formed of a plurality of second metal plate portions (for example, the metal plate portions 81) that are disposed to overlap. The first metal plate portion contains a first material. The second metal plate portion contains a second material. The thermal conductivity of the first material is higher than the thermal conductivity of the second material.

According to such a constitution, since the first routing portion provided between the first electronic component and the second electronic component is formed of the metal plate portion made of the first material having a high thermal conductivity, it is possible to favorably dissipate heat of the first electronic component which is likely to have a relatively high temperature. On the other hand, since the second routing portion that is less likely to be affected by heat from the first electronic component than the first routing portion is made of the second material that is inexpensive and/or has a smaller specific gravity than the first material, it is possible to reduce the cost and/or weight related to the routing structure. With this structure, the heat dissipation property of the electrical connection unit can be improved, and the cost and/or weight can be reduced.

Here, in a case where the routing portion is formed of one metal plate having a large plate thickness, the metal plate becomes expensive, and it may be difficult to reduce the cost of the electrical connection unit. On the other hand, in the present embodiment, the second routing portion is formed of a plurality of metal plates that are disposed to overlap, and thus the cost related to the routing structure can be reduced compared with the case where the routing portion is formed of one metal plate having a large plate thickness. As a result, it is possible to further reduce the cost of the electrical connection unit.

In the present embodiment, the number of the at least one first metal plate portion is smaller than the number of the plurality of second metal plate portions. According to such a constitution, for example, the use amount of the first material that is more expensive and/or has a larger specific gravity than the second material can be reduced. With this structure, it is possible to further reduce the cost and/or weight of the electrical connection unit.

In the present embodiment, the total thickness of the at least one first metal plate portion in the first direction is smaller than the total thickness of the plurality of second metal plate portions in the first direction. According to such a constitution, for example, the use amount of the first material that is more expensive and/or has a larger specific gravity than the second material can be reduced. With this structure, it is possible to further reduce the cost and/or weight of the electrical connection unit. According to the above constitution, the height of the electrical connection unit can be reduced.

In the present embodiment, the thickness of the single body of the first metal plate portion in the first direction is larger than the thickness of the single body of the second metal plate portion in the first direction. According to such a constitution, the heat dissipation property of the first routing portion can be enhanced while reducing the number of first metal plate portions. With this structure, the heat dissipation property of the electrical connection unit can be further improved.

In the present embodiment, the first routing portion has a first attachment surface (for example, the first attachment surface S11) facing the first terminal or a routing member (for example, the connection component 30) connected to the first terminal. The second routing portion has a second attachment surface (for example, a second attachment surface S12) facing the second terminal or a routing member (for example, the connection component 30) connected to the second terminal. The first attachment surface and the second attachment surface are located on the same plane. According to such a constitution, even in a case where the first routing portion and the second routing portion have different thicknesses, since the two attachment surfaces facing the terminal or the routing member (for example, the connection component 30) of the electronic component are located on the same plane, it becomes easier to attach the electronic component. As a result, it is possible to further reduce the cost of the electrical connection unit.

According to still another aspect, the above-described fourth structure SD can be described as follows. The fourth structure SD includes a first electronic component (for example, the electronic component 20H), a second electronic component (for example, the electronic component 20E), a first component (for example, the electronic component 20F), a first routing portion (for example, the routing portion 70M), and a second routing portion (for example, the routing portion 70N). The second electronic component has a first terminal (for example, the terminal 23A) and a second terminal (for example, the terminal 23B). The first component has a smaller amount of heat generation than the first electronic component during energization. The first routing portion (for example, the routing portion 70M) is connected to the first terminal of the second electronic component, and electrically connects the first electronic component to the second electronic component. The second routing portion (for example, the routing portion 70N) is connected to the second terminal of the second electronic component, and electrically connects the second electronic component to the first component. The first routing portion is formed of at least one first metal plate portion (for example, the metal plate portion 83). The second routing portion is formed of a plurality of second metal plate portions (for example, the metal plate portions 81) that are disposed to overlap in the Z direction. The first metal plate portion contains a first material. The second metal plate portion contains a second material. The thermal conductivity of the first material is higher than the thermal conductivity of the second material.

According to such a constitution, since the first routing portion provided between the first electronic component and the second electronic component is formed of the metal plate portion made of the first material having a high thermal conductivity, it is possible to favorably dissipate heat of the first electronic component which is likely to have a relatively high temperature. On the other hand, since the second routing portion provided between the second electronic component and the first component is made of the second material that is inexpensive and/or has a smaller specific gravity than the first material, it is possible to reduce the cost and/or weight related to the routing structure. With this structure, the heat dissipation property of the electrical connection unit can be improved, and the cost and/or weight can be reduced.

In the above relationship, the second electronic component (electronic component 20E) is not limited to an electronic component that has a smaller amount of heat generation than the first electronic component (electronic component 20H) during energization. The second electronic component (electronic component 20E) may be an electronic component having an amount of heat generation equal to or greater than that of the first electronic component (electronic component 20H) during energization.

### 5.6 Viewpoint of Combination of Fourth Structure and First Structure

In the present embodiment, the electronic component 20H included in the fourth structure SD has a greater amount of heat generation than the electronic component 20A included in the first structure SA during energization. Thus, the electrical connection unit 1 can be described as follows.

The electrical connection unit 1 includes a first electronic component (for example, the electronic component 20H of the fourth structure SD), a second electronic component (for example, the electronic component 20E of the fourth structure SD), a third electronic component (for example, the electronic component 20A of the first structure SA), a fourth electronic component (for example, the electronic component 20B of the first structure SA), a first routing portion (for example, the routing portion 70M of the fourth structure SD), and a second routing portion (for example, the routing portion 70A of the first structure SA). The third electronic component has a smaller amount of heat generation than the first electronic component during energization. The first routing portion electrically connects the first electronic component to the second electronic component. The second routing portion electrically connects the third electronic component to the fourth electronic component. The first routing portion is formed of at least one first metal plate portion (for example, the metal plate portion 83). The second routing portion is formed of a plurality of second metal plate portions (for example, the metal plate portions 81) that are disposed to overlap in the Z direction. The first metal plate portion contains a first material. The second metal plate portion contains a second material. The thermal conductivity of the first material is higher than the thermal conductivity of the second material.

According to such a constitution, since the first routing portion provided between the first electronic component and the second electronic component is formed of the metal plate portion made of the first material having a high thermal conductivity, it is possible to favorably dissipate heat of the first electronic component which is likely to have a relatively high temperature. On the other hand, since the second routing portion provided between the third electronic component and the fourth electronic component is made of the second material that is inexpensive and/or has a smaller specific gravity than the first material, it is possible to reduce the cost and/or weight related to the routing structure. With this structure, the heat dissipation property of the electrical connection unit can be improved, and the cost and/or weight can be reduced.

From still another viewpoint, the electrical connection unit 1 can be described as follows. The electrical connection unit 1 includes the electronic component 20H (of which the amount of heat generation is relatively large), the electronic components 20A, 20B, 20E, and 20F (of which the amount of heat generation is relatively medium), and a first component (of which the amount of heat generation is relatively small) that is the external connection terminal 50 or the electronic component 20DA.

The routing portion 70M connecting the electronic component 20H having a relatively great amount of heat generation and the electronic component 20E having a relatively medium amount of heat generation is formed of at least one metal plate portion 83 containing the first material having a high thermal conductivity. On the other hand, the routing portion 70A connecting the electronic component 20A and the electronic component 20B each having a relatively medium amount of heat generation is formed of the first number (for example, two) of metal plate portions 81 containing the second material and disposed to overlap. Similarly, the routing portion 70N connecting the electronic component 20E and the electronic component 20F each having a relatively medium amount of heat generation is formed of the first number (for example, two) of metal plate portions 81 containing the second material and disposed to overlap. The routing portion 70B connecting the electronic component 20A having a relatively medium amount of heat generation and the first component having a relatively small amount of heat generation is formed of the second number (for example, one) of metal plate portions 82 containing the second material. According to such a constitution, three types of routing portions having different heat dissipation characteristics according to the magnitude of the amount of heat generation of the component are provided. With this constitution, it is possible to further improve the heat dissipation property of the electrical connection unit and reduce the cost.

### 5.7 Viewpoint of Combination of Fourth Structure and Second Structure

In the present embodiment, the electronic component 20H included in the fourth structure SD has a greater amount of heat generation than the electronic component 20E included in the second structure SB during energization. Thus, the electrical connection unit 1 can be described as follows.

The electrical connection unit 1 includes a first electronic component (for example, the electronic component 20H of the fourth structure SD), a second electronic component (for example, the electronic component 20E of the fourth structure SD), a third electronic component (for example, the electronic component 20E of the second structure SB), a fourth electronic component (for example, the electronic component 20F or the electronic component 20G of the second structure SB), a first routing portion (for example, the routing portion 70M of the fourth structure SD), and a second routing portion (for example, the routing portion 70F of the second structure SB). The third electronic component has a smaller amount of heat generation than the first electronic component during energization. The first routing portion electrically connects the first electronic component to the second electronic component. The second routing portion electrically connects the third electronic component to the fourth electronic component. The first routing portion is formed of at least one first metal plate portion (for example, the metal plate portion 83). The second routing portion is formed of a plurality of second metal plate portions (for example, the metal plate portions 81) that are disposed to overlap in the Z direction. The first metal plate portion contains a first material. The second metal plate portion contains a second material. The thermal conductivity of the first material is higher than the thermal conductivity of the second material. According to this constitution, similarly to the above-described constitution, it is possible to improve the heat dissipation property of the electrical connection unit and to reduce the cost and/or weight thereof.

From still another viewpoint, the electrical connection unit 1 can be described as follows. The electrical connection unit 1 includes the electronic component 20H (of which the amount of heat generation is relatively great), the electronic components 20E and 20F (of which the amount of heat generation is relatively medium), the electronic component 20G (of which the amount of heat generation is relatively medium or small), and a first component (of which the amount of heat generation is relatively small) that is the external connection terminal 50 or the electronic component 20D.

The routing portion 70M connecting the electronic component 20H having a relatively great amount of heat generation and the electronic component 20E having a relatively medium amount of heat generation is formed of at least one metal plate portion 83 containing the first material having a high thermal conductivity. On the other hand, the routing portion 70N connecting the electronic component 20E and the electronic component 20F each having a relatively medium amount of heat generation is formed of the first number (for example, two) of metal plate portions 81 containing the second material and disposed to overlap. Similarly, the routing portion 70F between the electronic component 20E having a relatively medium amount of heat generation and the electronic component 20G having a relatively medium or small amount of heat generation is formed of the first number (for example, two) of metal plate portions 81 containing the second material and disposed to overlap. The routing portion 70G connecting the electronic component 20G having a relatively medium or small amount of heat generation to the first component having a relatively small amount of heat generation is formed of the second number (for example, one) of metal plate portions 82 containing the second material. According to such a constitution, three types of routing portions having different heat dissipation characteristics according to the magnitude of the amount of heat generation of the component are provided. With this constitution, it is possible to further improve the heat dissipation property of the electrical connection unit and reduce the cost.

### 6. Fifth Structure

Next, the fifth structure SE will be described.

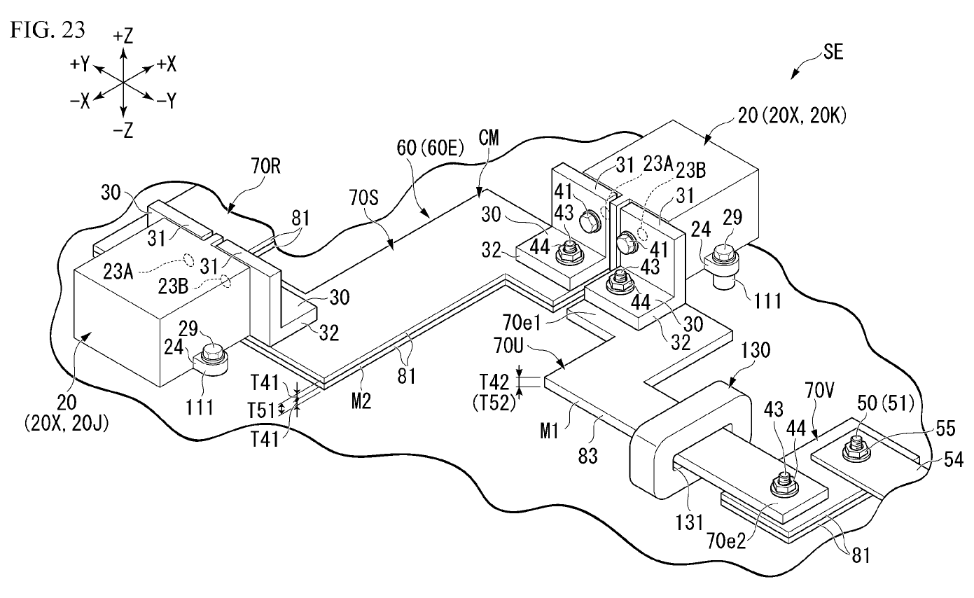

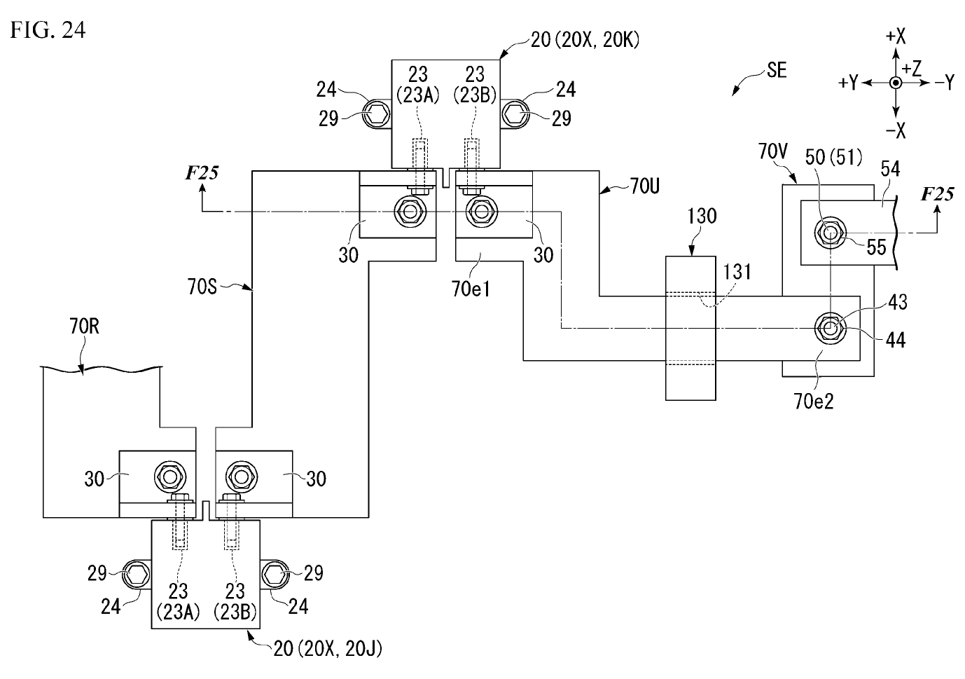

FIG. 23 is a perspective view illustrating the fifth structure SE. FIG. 24 is a plan view illustrating the fifth structure SE. The fifth structure SE includes, for example, a plurality of electronic components 20, a plurality of connection components 30, an external connection terminal 50, a routing structure 60, and a sensor 130.

### 6.1 Electronic Component

The fifth structure SE includes two electronic components 20J and 20K as the plurality of electronic components 20. The electronic components 20J and 20K are, for example, components included in the main circuit CM of the electrical connection unit 1. The two electronic components 20J and 20K are electrically connected in series to each other, for example. Each of the electronic components 20J and 20K is, for example, a relay. However, the types of the electronic components 20J and 20K are not limited to the above example.

### 6.2 Sensor

The sensor 130 is a sensor for measuring a physical quantity related to the electrical connection unit 1. The sensor 130 is, for example, a current sensor. However, the type of the sensor 130 is not limited to the above example. The sensor 130 includes an insertion portion 131 through which a routing portion 70U that will be described later passes. The insertion portion 131 penetrates the sensor 130 in the horizontal direction (for example, the Y direction). The sensor 130 is formed in, for example, an annular shape.

### 6.3 Routing Structure

The fifth structure SE includes a routing structure 60E as the routing structure 60. The routing structure 60E includes a routing portion 70R, a routing portion 70S, a routing portion 70U, and a routing portion 70V.

### Routing Portion 70R

The routing portion 70R is a routing portion connected to the electronic component 20J and another portion of the electrical connection unit 1. For example, the routing portion 70R is connected to the connection component 30 corresponding to the terminal 23A of the electronic component 20J, and is electrically connected to the terminal 23A of the electronic component 20J via the connection component 30. Note that the routing portion 70R may be directly connected to the terminal 23A of the electronic component 20J.

### Routing Portion 70S

The routing portion 70S is provided over the electronic component 20J and the electronic component 20K, and electrically connects the electronic component 20J to the electronic component 20K. For example, the routing portion 70S is connected to the connection component 30 corresponding to the terminal 23B of the electronic component 20J, and is electrically connected to the terminal 23B of the electronic component 20J via the connection component 30. The routing portion 70S is connected to the connection component 30 corresponding to the terminal 23A of the electronic component 20K, and is electrically connected to the terminal 23A of the electronic component 20K via the connection component 30. Note that, instead of the above example, the routing portion 70S may be directly connected to the terminal 23B of the electronic component 20J. The routing portion 70S may be directly connected to the terminal 23A of the electronic component 20K. The routing portion 70S is an example of a “second routing portion”.

### Routing Portion 70U

The routing portion 70U is provided over the electronic component 20K and another routing portion 70V, and electrically connects the electronic component 20K to another routing portion 70V. For example, the routing portion 70U is connected to the connection component 30 corresponding to the terminal 23B of the electronic component 20K, and is electrically connected to the terminal 23B of the electronic component 20K via the connection component 30. The routing portion 70U is connected to another routing portion 70V. Note that, instead of the above example, the routing portion 70U may be directly connected to the terminal 23B of the electronic component 20K. The routing portion 70U may be connected to another electronic component 20 directly or via the connection component 30 instead of another routing portion 70V.

The routing portion 70U extends through the insertion portion 131 of the sensor 130. The routing portion 70U has, for example, a first end portion 70e1 and a second end portion 70e2. The first end portion 70e1 is connected to the connection component 30 corresponding to the electronic component 20K, and is electrically connected to the electronic component 20K via the connection component 30. The second end portion 70e2 is an end portion opposite to the first end portion 70e1. The second end portion 70e2 is connected to the routing portion 70V. The routing portion 70U is an example of a “first routing portion”.

### Routing Portion 70V

The routing portion 70V is located on the side opposite to the electronic component 20K with respect to the sensor 130. The routing portion 70V is directly connected to the routing portion 70U. Note that the routing portion 70V may be connected to the routing portion 70U via the connection component 30 (for example, the connection component 30Y). The routing portion 70V is an example of a “third routing portion”.

The routing portion 70V is provided over the routing portion 70U and the external connection terminal 50, and electrically connects the routing portion 70U to the external connection terminal 50. For example, the routing portion 70V is fixed to the routing portion 70U via the fastening member 43 and the engagement member 44. The external connection terminal 50 is provided in the routing portion 70V. The external connection terminal 50 protrudes in the Z direction from the routing portion 70V, for example.

### 6.4 Material and Thickness of Routing Structure

In the present embodiment, the routing portion 70U is formed of at least one metal plate portion 83. In the present embodiment, the routing portion 70U is formed of one metal plate portion 83. However, the routing portion 70U may be formed of a plurality of metal plate portions 83 that are disposed to overlap in the Z direction. The metal plate portion 83 is a plate portion provided in the horizontal direction. The metal plate portion 83 contains the first material M1 described above. The first material M1 is, for example, copper or a copper alloy. A plate thickness (the thickness in the Z direction) T42 of the metal plate portion 83 is, for example, 5 mm. The metal plate portion 83 is an example of a “first metal plate portion”.

In the present embodiment, each of the routing portion 70R, the routing portion 70S, and the routing portion 70V is formed of a plurality of (for example, two) metal plate portions 81. The metal plate portion 81 is a plate portion provided in the horizontal direction. The metal plate portion 81 contains the second material M2 described above. The second material M2 is, for example, aluminum or an aluminum alloy. A plate thickness (the thickness in the Z direction) T41 of the metal plate portion 81 is, for example, 3 mm. The metal plate portion 81 included in the routing portion 70S is an example of a “second metal plate portion”. The metal plate portion 81 included in the routing portion 70V is an example of a “third metal plate portion”.

In the present embodiment, the number of metal plate portions 83 is smaller than the number of metal plate portions 81. However, the number of metal plate portions 83 may be the same as or larger than the number of the metal plate portions 81.

In the present embodiment, the total thickness T52 (for example, 5 mm) of the at least one metal plate portion 83 in the Z direction is smaller than the total thickness T51 (for example, 6 mm) of the plurality of metal plate portions 81 in the Z direction. In other words, the thickness of the routing portion 70M in the Z direction is smaller than the thickness of each of the routing portion 70R, the routing portion 70S, and the routing portion 70V in the Z direction.

On the other hand, the thickness T42 (for example, 5 mm) of the single metal plate portion 83 in the Z direction is larger than the thickness T41 (for example, 3 mm) of the single metal plate portion 81 in the Z direction.

### 6.5 Cross-Sectional Structure of Fifth Structure

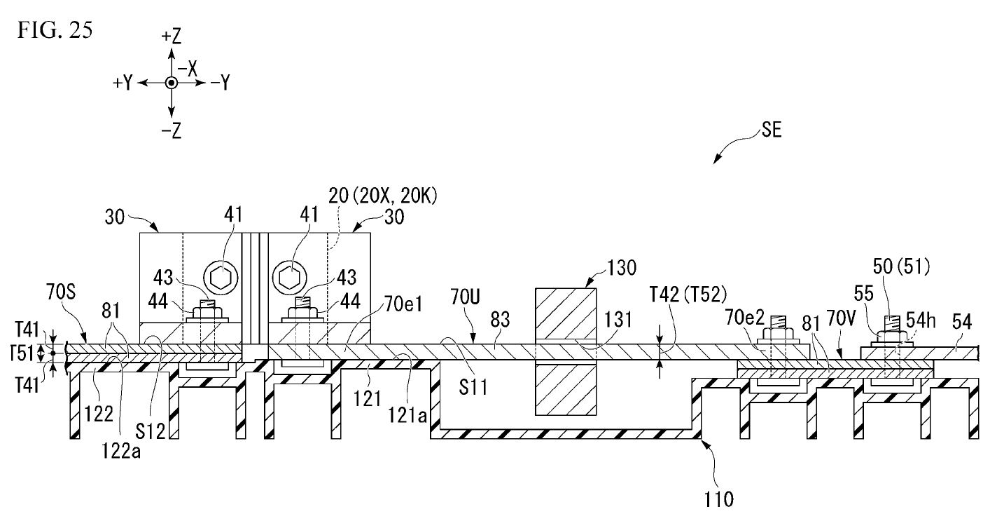

FIG. 25 is a cross-sectional view taken along line F25-F25 of the structure illustrated in FIG. 24. In the present embodiment, the routing portion 70U has a first attachment surface S11. The first attachment surface S11 faces the connection component 30 corresponding to the terminal 23B of the electronic component 20K from below. For example, the first attachment surface S11 is in contact with the connection component 30 corresponding to the terminal 23B of the electronic component 20K from below. The first attachment surface S11 may be in contact with the terminal 23B of the electronic component 20K.

The routing portion 70S has a second attachment surface S12. The second attachment surface S12 faces the connection component 30 corresponding to the terminal 23A of the electronic component 20K from below. For example, the second attachment surface S12 is in contact with the connection component 30 corresponding to the terminal 23A of the electronic component 20K from below. The second attachment surface S12 may be in contact with the terminal 23A of the electronic component 20K. In the present embodiment, the first attachment surface S11 of the routing portion 70U and the second attachment surface S12 of the routing portion 70S are located on the same plane.

In the present embodiment, the base member 110 includes a first support portion 121 and a second support portion 122. The first support portion 121 supports the routing portion 70U from below. The second support portion 122 supports the routing portion 70S from below. In the present embodiment, the first support portion 121 and the second support portion 122 are provided at different positions corresponding to the difference between the thickness of the routing portion 70U in the Z direction and the thickness of the routing portion 70S in the Z direction. For example, the end surface 122a of the second support portion 122 on the +Z direction side is located on the -Z direction side with respect to the end surface 121a of the first support portion 121 on the +Z direction side.

### 6.6 Advantages of Fifth Structure

As a comparative example, a constitution in which each routing portion is formed thick in order to enhance a heat dissipation property in the entire region of the electrical connection unit will be considered. In such a constitution of the comparative example, there may be a case where the routing portion becomes thick and cannot pass through the insertion portion of the sensor.

Therefore, the electrical connection unit of the present embodiment includes an electronic component (for example, the electronic component 20K), a sensor (for example, the sensor 130), a first routing portion (for example, the routing portion 70U), and a second routing portion (for example, the routing portion 70V). The electronic component has a first terminal (for example, the terminal 23B) and a second terminal (for example, the terminal 23A). The sensor includes an insertion portion (for example, the insertion portion 131). The first routing portion passes through the insertion portion and is connected to the first terminal directly or via a routing member. The second routing portion is connected to the second terminal directly or via a routing member. The thickness of the first routing portion is smaller than the thickness of the second routing portion. The first routing portion contains a first material. The second routing portion contains a second material. The thermal conductivity of the first material is higher than the thermal conductivity of the second material.

According to such a constitution, since the first routing portion inserted into the insertion portion of the sensor is formed of the metal plate portion made of the first material having a high thermal conductivity, it is possible to curb a large temperature rise even when the first routing portion is thinner than the second routing portion. With this structure, in the constitution in which the sensor having the insertion portion is provided, the heat dissipation property of the electrical connection unit can be improved.

In the present embodiment, the first routing portion is formed of at least one first metal plate portion (for example, the metal plate portion 83). The second routing portion is formed of a plurality of second metal plate portions (for example, the metal plate portions 81) that are disposed to overlap. According to such a constitution, the cost related to the routing structure can be reduced compared with a case where the second routing portion is formed of one metal plate having a large plate thickness. As a result, it is possible to further reduce the cost of the electrical connection unit.

In the present embodiment, the number of the at least one first metal plate portion is smaller than the number of the plurality of second metal plate portions. According to this constitution, for example, the use amount of the first material that is more expensive and/or has a larger specific gravity than the second material can be reduced. With this structure, it is possible to further reduce the cost and/or weight of the electrical connection unit.

In the present embodiment, the total thickness of the at least one first metal plate portion in the first direction is smaller than the total thickness of the plurality of second metal plate portions in the first direction. According to such a constitution, for example, the use amount of the first material that is more expensive and/or has a larger specific gravity than the second material can be reduced. With this structure, it is possible to further reduce the cost and/or weight of the electrical connection unit. According to the above constitution, the height of the electrical connection unit can be reduced.

In the present embodiment, the electrical connection unit further includes a third routing portion (for example, the routing portion 70V) located on the side opposite to the electronic component with respect to the sensor and connected to the first routing portion directly or via a routing member. The third routing portion is formed of a plurality of third metal plate portions (for example, the metal plate portions 81) that are disposed to overlap. According to such a constitution, each of the second routing portion and the third routing portion located on both sides of the first routing portion that passes through the insertion portion of the sensor is formed of the plurality of metal plate portions. Thus, the heat dissipation property of the electrical connection unit can be further improved.

Several embodiments and modification examples have been described above. However, the embodiments and the modification examples are not limited to the examples described above. For example, the above-described first to fifth structures SA, SB, SC, SD, and SE may be implemented in combination with each other. In the above-described embodiment, the case where an example of the “first number” is two and an example of the “second number” is one has been described. However, the “first number” and the “second number” are not limited to the above examples. For example, the “first number” may be three or more. The “second number” may be two or more.

While preferred embodiments of the invention have been described and illustrated above, it should be understood that these are exemplary examples of the invention and are not to be considered as limiting. Additions, omissions, substitutions, and other modifications can be made without departing from the scope of the present invention. Accordingly, the invention is not to be considered as being limited by the foregoing description, and is only limited by the scope of the appended claims.

### REFERENCE SIGNS LIST

1 Electrical connection unit

20, 20A, 20B, 20C, 20D, 20DA, 20DB, 20E, 20F, 20G, 20H, 20J, 20K Electronic component

30 Connection component (routing member)

60, 60A, 60B, 60C, 60D, 60E Routing structure

65 Routing structure

70A, 70B, 70C, 70D, 70E, 70F, 70G, 70H, 70I, 70J, 70K, 70L, 70M, 70N, 70P, 70R, 70S, 70U, 70V Routing portion

81 Metal plate portion

82 Metal plate portion

91 Metal plate

92 Metal plate

110 Base member

121 First support portion

122 Second support portion

123 Third support portion

124 Fourth support portion

130 Sensor

131 Insertion portion

What is claimed is:

1. An electrical connection unit comprising:
a first electronic component;
a second electronic component that includes a first terminal and a second terminal, and has a smaller amount of heat generation than the first electronic component during energization;
a first routing portion that is connected to the first terminal of the second electronic component directly or via a routing member and electrically connects the first electronic component to the second electronic component; and
a second routing portion that is connected to the second terminal of the second electronic component directly or via a routing member,
wherein the first routing portion is formed of at least one first metal plate portion,
the second routing portion is formed of a plurality of second metal plate portions that are disposed to overlap,
the first metal plate portion contains a first material,
the second metal plate portion contains a second material, and
a thermal conductivity of the first material is higher than a thermal conductivity of the second material.

2. The electrical connection unit according to claim 1, wherein
the first material is copper or a copper alloy, and
the second material is aluminum or an aluminum alloy.

3. The electrical connection unit according to claim 1, wherein
the number of the at least one first metal plate portion is smaller than the number of the plurality of second metal plate portions.

4. The electrical connection unit according to claim 1, wherein
in a case where a plate thickness direction of the first metal plate portion is a first direction,
a total thickness of the at least one first metal plate portion in the first direction is smaller than a total thickness of the plurality of second metal plate portions in the first direction.

5. The electrical connection unit according to claim 4, wherein
a thickness of a single plate of the first metal plate portion in the first direction is larger than a thickness of a single plate of the second metal plate portions in the first direction.

6. The electrical connection unit according to claim 1, wherein
the first routing portion has a first attachment surface facing the first terminal or a routing member connected to the first terminal,
the second routing portion has a second attachment surface facing the second terminal or a routing member connected to the second terminal, and
the first attachment surface and the second attachment surface are located on the same plane.

7. An electrical connection unit comprising:
a first electronic component;
a second electronic component that includes a first terminal and a second terminal;
a first component that has a smaller amount of heat generation than the first electronic component during energization;
a first routing portion that is connected to the first terminal of the second electronic component directly or via a routing member and electrically connects the first electronic component to the second electronic component; and
a second routing portion that is connected to the second terminal of the second electronic component directly or via a routing member and electrically connects the second electronic component to the first component,
wherein the first routing portion is formed of at least one first metal plate portion,
the second routing portion is formed by a plurality of second metal plate portions that are disposed to overlap,
the first metal plate portion contains a first material,
the second metal plate portion contains a second material, and
a thermal conductivity of the first material is higher than a thermal conductivity of the second material.

8. An electrical connection unit comprising:
a first electronic component;
a second electronic component;
a third electronic component that has a smaller amount of heat generation than the first electronic component during energization;
a fourth electronic component;
a first routing portion that electrically connects the first electronic component to the second electronic component; and
a second routing portion that electrically connects the third electronic component to the fourth electronic component,
wherein the first routing portion is formed of at least one first metal plate portion,
the second routing portion is formed of a plurality of second metal plate portions that are disposed to overlap,
the first metal plate portion contains a first material,
the second metal plate portion contains a second material, and
a thermal conductivity of the first material is higher than a thermal conductivity of the second material.
